(19) United States
(12) Patent Application Publication
(10) Pub. No.: US 2026/0251932 A1
(43) Pub. Date: Aug. 27, 2026

(54) COLOR CONVERSION SUBSTRATE AND MANUFACTURING METHOD THEREOF, AND DISPLAY PANEL

(71) Applicant: BOE TECHNOLOGY GROUP CO., LTD., Beijing (CN)

(72) Inventors: Shuaifeng ZHANG, Beijing (CN); Haiyan SUN, Beijing (CN); Xiaojin ZHANG, Beijing (CN); Dan WANG, Beijing (CN)

(73) Assignee: BOE TECHNOLOGY GROUP CO., LTD., Beijing (CN)

(21) Appl. No.: 18/870,638

(22) PCT Filed: Aug. 27, 2024
(86) PCT No.: PCT/CN2024/114828

§ 371 Date: Nov. 29, 2024

(30) Foreign Application Priority Data
Sep. 27, 2023 (CN) 202311270313.4

(51) Int. Cl. G02F 1/1335; G02F 1/13363; G02F 1/1337; G02F 1/135; H10K 59/38

(52) U.S. Cl. CPC G02F 1/133516; G02F 1/133636; G02F 1/1337; G02F 1/1351; G02F 1/1352; H10K 59/38

(57) ABSTRACT

Embodiments of the present disclosure provide a color conversion substrate. The color conversion substrate includes a substrate, a color conversion layer and a cholesteric liquid crystal layer. The color conversion layer is located on a side of the substrate; the color conversion layer includes a first color conversion portion; the first color conversion portion is configured to convert first color light incident on the first color conversion portion into second color light. The cholesteric liquid crystal layer includes a first cholesteric liquid crystal unit located between the substrate and the first color conversion portion; the first cholesteric liquid crystal unit is configured to reflect unconverted light in the first color light back to the first color conversion portion.

### CROSS-REFERENCE TO RELATED APPLICATIONS

This application is a national phase entry under 35 USC 371 of International Patent Application No. PCT/CN2024/114828, filed on Aug. 27, 2024, which claims priority to Chinese Patent Application No. 202311270313.4, filed on Sep. 27, 2023, which are incorporated herein by reference in their entirety.

### TECHNICAL FIELD

The present disclosure relates to the field of display technologies, and in particular, to a color conversion substrate and a manufacturing method thereof, and a display panel.

### BACKGROUND

In the display field, the color conversion substrate is widely applied to achieve full-color display of a display panel. Specifically, the light emitted by a light-emitting substrate of the display panel is used as excitation light to excite the color conversion material in the color conversion substrate to convert the color of at least a part of the excitation light, so that the display panel outputs light of various colors such as red, green and blue to achieve the purpose of full-color display.

### SUMMARY

In an aspect, a color conversion substrate is provided. The color conversion substrate includes a substrate, a color conversion layer and a cholesteric liquid crystal layer. The color conversion layer is located on a side of the substrate; the color conversion layer includes a first color conversion portion; the first color conversion portion is configured to convert first color light incident on the first color conversion portion into second color light. The cholesteric liquid crystal layer includes a first cholesteric liquid crystal unit located between the substrate and the first color conversion portion; the first cholesteric liquid crystal unit is configured to reflect unconverted light in the first color light back to the first color conversion portion.

In some embodiments, the color conversion layer further includes a second color conversion portion arranged in a first direction with the first color conversion portion, the first direction intersects with a thickness direction of the substrate, and the second color conversion portion is configured to convert first color light incident on the second color conversion portion into third color light. The cholesteric liquid crystal layer further includes a second cholesteric liquid crystal unit located between the substrate and the second color conversion portion; the second cholesteric liquid crystal unit is configured to reflect unconverted light in the first color light back to the second color conversion portion.

In some embodiments, cholesteric liquid crystals in the first cholesteric liquid crystal unit and the second cholesteric liquid crystal unit are in a planar state.

In some embodiments, the color conversion substrate further includes a light-transmitting portion arranged in a first direction with the color conversion layer, the first direction intersects with a thickness direction of the substrate, and the first color light passes through the light-transmitting portion. The cholesteric liquid crystal layer further includes a third cholesteric liquid crystal unit located between the substrate and the light-transmitting portion; the third cholesteric liquid crystal unit is configured to scatter a part of the first color light passing through the light-transmitting portion that near a front viewing angle toward a large viewing angle direction.

In some embodiments, cholesteric liquid crystals in the third cholesteric liquid crystal unit are in a focal conic state.

In some embodiments, the first cholesteric liquid crystal unit includes a first chiral liquid crystal unit and a second chiral liquid crystal unit that are stacked, a helical direction of liquid crystal molecules in the first chiral liquid crystal unit is opposite to a helical direction of liquid crystal molecules in the second chiral liquid crystal unit; and/or the cholesteric liquid crystal layer further includes a second cholesteric liquid crystal unit, the second cholesteric liquid crystal unit includes a third chiral liquid crystal unit and a fourth chiral liquid crystal unit that are stacked, and a helical direction of liquid crystal molecules in the third chiral liquid crystal unit is opposite to a helical direction of liquid crystal molecules in the fourth chiral liquid crystal unit.

In some embodiments, a pitch of liquid crystal molecules in the first cholesteric liquid crystal unit is greater than or equal to 270 nm and less than or equal to 310 nm; a pitch of liquid crystal molecules in the second cholesteric liquid crystal unit is greater than or equal to 270 nm and less than or equal to 310 nm.

In some embodiments, the first color light is blue light. A central reflection wavelength of the first cholesteric liquid crystal unit is greater than or equal to 450 nm and less than or equal to 470 nm; a central reflection wavelength of the second cholesteric liquid crystal unit is greater than or equal to 450 nm and less than or equal to 470 nm.

In some embodiments, a full width at half maxima of a transmission spectrum of the first cholesteric liquid crystal unit is greater than or equal to 70 nm and less than or equal to 100 nm; a full width at half maxima of a transmission spectrum of the second cholesteric liquid crystal unit is greater than or equal to 70 nm and less than or equal to 100 nm.

In some embodiments, the color conversion substrate further includes an alignment layer located between the cholesteric liquid crystal layer and the substrate. The alignment layer includes a first alignment portion, a second alignment portion and a third alignment portion that are arranged in the first direction. The first alignment portion is configured to align liquid crystal molecules in the first cholesteric liquid crystal unit. The second alignment portion is configured to align liquid crystal molecules in the second cholesteric liquid crystal unit. The third alignment portion is configured to align liquid crystal molecules in the third cholesteric liquid crystal unit.

In some embodiments, haze of the third cholesteric liquid crystal unit is greater than or equal to 3% and less than or equal to 8%.

In some embodiments, a transmittance of the third cholesteric liquid crystal unit to light in a first wavelength band is greater than or equal to 90%. The minimum wavelength of the first wavelength band is 450 nm, and the maximum wavelength of the first wavelength band is 470 nm.

In some embodiments, a thickness of the cholesteric liquid crystal layer is greater than or equal to 2 μm and less than or equal to 6 μm.

In some embodiments, a material of the first color conversion portion includes a first quantum dot material. A material of the second color conversion portion includes a second quantum dot material.

In some embodiments, the color conversion substrate further includes a barrier pattern. The barrier pattern includes a plurality of first openings. The first color conversion portion and the first cholesteric liquid crystal unit are located in a first opening. The second color conversion portion and the second cholesteric liquid crystal unit are located in another first opening. The light-transmitting portion and the third cholesteric liquid crystal unit are located in yet another first opening.

In some embodiments, the color conversion substrate further includes a light-blocking layer located between the cholesteric liquid crystal layer and the substrate. The light-blocking layer includes a light-absorbing pattern and a plurality of color filter portions. The light-absorbing pattern includes a plurality of second openings, and the plurality of second openings are directly opposite to the plurality of first openings. The plurality of color filter portions are located on a side of the substrate proximate to the cholesteric liquid crystal layer; a color filter portion of the plurality of color filter portions is disposed in a second opening of the plurality of second openings. The plurality of color filter portions include a first color filter portion directly opposite to the first color conversion portion, a second color filter portion directly opposite to the second color conversion portion, and a third color filter portion directly opposite to the light-transmitting portion.

In another aspect, a manufacturing method of a color conversion substrate is provided. The manufacturing method includes the following steps. Providing a substrate. Forming a cholesteric liquid crystal layer on a side of the substrate; the cholesteric liquid crystal layer including a first cholesteric liquid crystal unit. Forming a color conversion layer on a side of the cholesteric liquid crystal layer away from the substrate; the color conversion layer including a first color conversion portion located on a side of the first cholesteric liquid crystal unit away from the substrate. In the above, the first color conversion portion is configured to convert first color light incident on the first color conversion portion into second color light; the first cholesteric liquid crystal unit is configured to reflect unconverted light in the first color light back to the first color conversion portion.

In some embodiments, the color conversion substrate further includes a light-transmitting portion arranged in a first direction with the color conversion layer, the first direction intersects with a thickness direction of the substrate, and the first color light is able to pass through the light-transmitting portion. The color conversion layer further includes a second color conversion portion arranged in the first direction with the first color conversion portion, and the second color conversion portion is configured to convert first color light incident on the second color conversion portion into third color light. The step of forming the cholesteric liquid crystal layer on the side of the substrate includes the following steps. Forming an initial cholesteric liquid crystal layer on the side of the substrate, and the initial cholesteric liquid crystal layer including a first initial cholesteric liquid crystal unit, a second initial cholesteric liquid crystal unit and a third initial cholesteric liquid crystal unit. Forming the first initial cholesteric liquid crystal unit into a first cholesteric liquid crystal unit, and forming the second initial cholesteric liquid crystal unit into a second cholesteric liquid crystal unit; the second cholesteric liquid crystal unit being located between the substrate and the second color conversion portion; and the second cholesteric liquid crystal unit being configured to reflect unconverted light in the first color light back to the second color conversion portion. Forming the third initial cholesteric liquid crystal unit into a third cholesteric liquid crystal unit; the third cholesteric liquid crystal unit being located between the substrate and the light-transmitting portion, and the third cholesteric liquid crystal unit being configured to scatter a part of the first color light passing through the light-transmitting portion that near a front viewing angle toward a large viewing angle direction.

In yet another aspect, a display panel is provided. The display panel includes the color conversion substrate according to any of the above embodiments and a light-emitting substrate. The light-emitting substrate is opposite to the color conversion substrate, and the light-emitting substrate is configured to emit the first color light.

In some embodiments, the light-emitting substrate includes any one of an organic light-emitting diode (OLED) light-emitting substrate, a light-emitting diode (LED) light-emitting substrate, a micro LED light-emitting substrate or a mini LED light-emitting substrate.

In some embodiments, the light-emitting substrate is an OLED light-emitting substrate, and the OLED light-emitting substrate includes a cathode and an anode disposed opposite to each other, and at least two light-emitting units disposed between the cathode and the anode. A light-emitting unit of the at least two light-emitting units includes a light-emitting layer, and the light-emitting layer is configured to emit the first color light toward the color conversion substrate.

### BRIEF DESCRIPTION OF THE DRAWINGS

In order to describe the technical solutions in the present disclosure more clearly, the accompanying drawings to be used in some embodiments of the present disclosure will be briefly introduced below. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display panel, in accordance with some embodiments;

FIG. 2 is a diagram showing light emission of a color conversion substrate, in accordance with some embodiments;

FIG. 3 is a structural diagram of a color conversion substrate, in accordance with some embodiments;

FIG. 4 is a structural diagram of another color conversion substrate, in accordance with some embodiments;

FIG. 5 is a diagram showing light emission of another color conversion substrate, in accordance with some embodiments;

FIG. 6 is a structural diagram of another display panel, in accordance with some embodiments;

FIG. 7 is a flow diagram of a manufacturing process of a color conversion substrate, in accordance with some embodiments;

FIG. 8 is a flow diagram of a manufacturing process of a cholesteric liquid crystal layer, in accordance with some embodiments;

FIG. 9 is a diagram showing a manufacturing process of a cholesteric liquid crystal layer, in accordance with some embodiments;

FIG. 10 is a structural diagram of yet another display panel, in accordance with some embodiments;

FIG. 11 is a diagram showing microscopic morphology of a first cholesteric liquid crystal unit, in accordance with some embodiments;

FIG. 12 is a diagram showing texture of a first cholesteric liquid crystal unit under a polarizing microscope, in accordance with some embodiments;

FIG. 13 is a diagram showing a transmission spectrum of a first cholesteric liquid crystal unit, in accordance with some embodiments;

FIG. 14 is a diagram showing microscopic morphology of a third cholesteric liquid crystal unit, in accordance with some embodiments;

FIG. 15 is a diagram showing texture of a third cholesteric liquid crystal unit under a polarizing microscope, in accordance with some embodiments; and

FIG. 16 is a diagram showing an angular distribution of light intensity of a third cholesteric liquid crystal unit, in accordance with some embodiments.

### DETAILED DESCRIPTION

The technical solutions in some embodiments of the present disclosure will be described clearly and completely below in conjunction with the accompanying drawings. Obviously, the embodiments to be described are merely some but not all embodiments of the present disclosure. All other embodiments obtained by a person of ordinary skill in the art based on the embodiments of the present disclosure should be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

The phrase “at least one of A, B and C” has a same meaning as the phrase “at least one of A, B or C”, both including the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The use of the phrase “applicable to” or “configured to” herein is meant to be an open and inclusive expression, which does not exclude devices that are applicable to or configured to perform additional tasks or steps.

In addition, the phrase “based on” used is meant to be open and inclusive, since a process, step, calculation or other action that is “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value, and the acceptable range of deviation is determined by a person of ordinary skill in the art, considering measurement in question and errors (i.e., limitations of a measurement system) associated with measurement of a particular quantity.

The term such as “parallel”, “perpendicular” or “equal” as used herein includes a stated condition and a condition similar to the stated condition within an acceptable range of deviation, and the acceptable range of deviation is determined by a person of ordinary skill in the art, considering measurement in question and errors (i.e., limitations of a measurement system) associated with measurement of a particular quantity. For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, in a case where a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

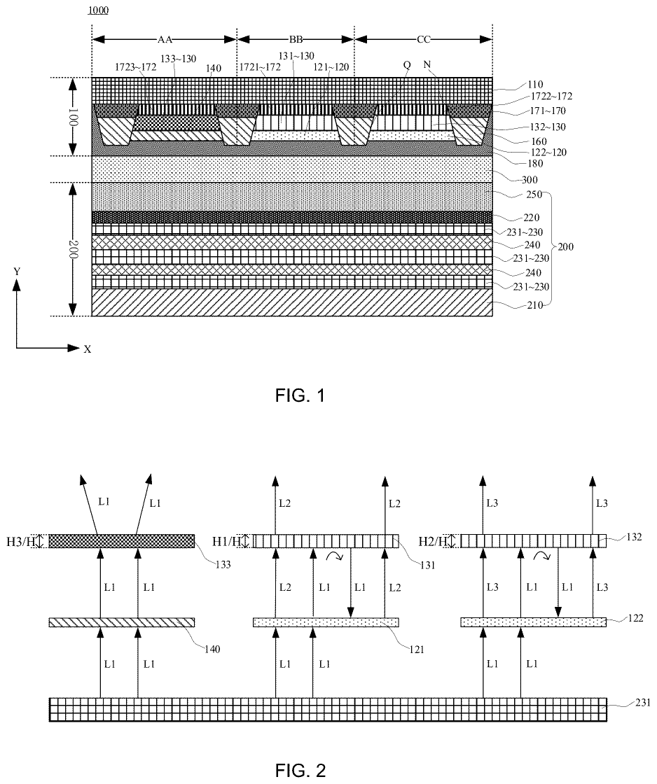

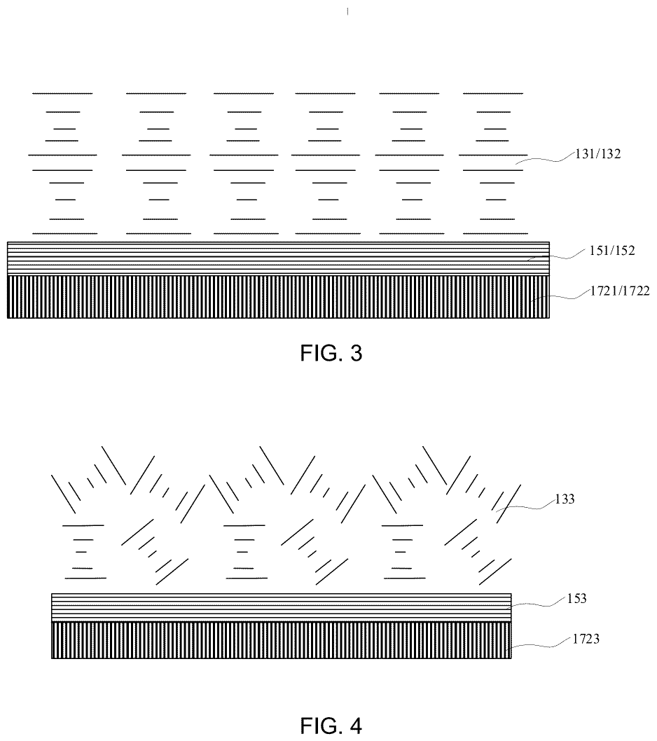

It will be noted that, “11~1”, for example, in the drawings of the present disclosure indicates that a component 11 belongs to a component 1; for example, “121~120” in FIG. 1 indicates that the first color conversion portion 121 belongs to the color conversion layer 120, and other similar signs appearing in the drawings also follow the above description. “1/2”, for example, appearing in the drawings of the present disclosure represents that a structure 1 and a structure 2 may both refer to this structure; for example, “131/132” in FIG. 3 represents that the first cholesteric liquid crystal unit 131 and the second cholesteric liquid crystal unit 132 may both refer to this structure, and other similar numbers appearing in the drawings also follow the above description.

At present, in the display field, a display panel achieves full-color display mainly through the following three methods.

The first method is an RGB pixel juxtaposition method, and the principle of which is to use luminescent materials of three colors of red (R), green (G) and blue (B) to emit light independently. In this method, red (R), green (G) and blue (B) are also referred to as the three primary colors; and the three primary colors are relatively pure, and the cost is relatively high. For example, in terms of light-emitting devices such as OLEDs, the OLED light-emitting devices of different colors may be formed by using a fine metal mask and an evaporation process in this method.

The second method is a method using a combination of a white light light-emitting substrate (e.g., white light LEDs) and color filters. In this method, the white light light-emitting devices are used as a backlight source to emit white light. The white light is filtered through the color filters into red, green and blue light. This method has a relatively low cost. However, due to the presence of the color filters, both the transmittance and the color purity of the light have certain limitations. Therefore, theoretically, the combination of white light light-emitting devices and the color filters is inferior to the RGB pixel juxtaposition method in terms of brightness, contrast, color and energy saving.

The third method, as described in the background and shown in FIG. 1, is a method using a combination of a light-emitting substrate 200 and a color conversion substrate 100. In this method, the light (e.g., blue light) emitted by the light-emitting substrate 200 of the display panel 1000 is used as excitation light to excite the color conversion material in the color conversion substrate 100 to convert the color of the excitation light, so that the display panel 1000 outputs light of various colors such as red, green and blue, so as to achieve the purpose of full-color display. For example, for the combination of blue light OLED light-emitting devices and the color conversion substrate 100, an open mask may be utilized to reduce the process difficulty, and the color conversion substrate 100 improves the utilization rate of light energy. Therefore, the color conversion substrate 100 is widely used to achieve full-color display of the display panel 1000.

In some embodiments, as shown in FIG. 1, for the method of combining the light-emitting substrate 200 and the color conversion substrate 100, a region emitting first color light L1 is a first sub-pixel region AA, a region emitting second color light L2 is a second sub-pixel region BB, and a region emitting third color light L3 is a third sub-pixel region CC. For example, the first color light L1 is blue light, the second color light L2 is red light, and the third color light L3 is green light.

In some embodiments, the excitation light emitted by the light-emitting substrate 200 is the first color light L1. In this case, the first color light L1 located in the first sub-pixel region AA may be directly emitted without passing through a color conversion material; the first color light L1 located in the second sub-pixel region BB is converted into the second color light L2 after passing through a color conversion material corresponding the second color and then emitted; the first color light L1 located in the third sub-pixel region CC is converted into the third color light L3 after passing through a color conversion material corresponding the third color and then emitted.

In some implementations, the color conversion material in the color conversion substrate fails to completely convert the first color light L1 (e.g., blue light) emitted by the light-emitting substrate, resulting in a problem of leakage of the first color light L1 caused by a fact that the unconverted first color light L1 is emitted from the second sub-pixel region BB and/or the third sub-pixel region CC. As a result, the second color light L2 (e.g., red light) emitted from the second sub-pixel region BB is mixed with the first color light L1 (e.g., blue light), and/or the third color light L3 (e.g., green light) emitted from the third sub-pixel region CC is mixed with the first color light L1 (e.g., blue light), which reduces the color purity of the display panel and affects the display effect.

In some other implementations, a film layer containing a color conversion material in a color conversion substrate is a color conversion layer, and the external quantum efficiency (EQE) of the color conversion layer is affected by the quantum yield and light extraction efficiency of the color conversion material. Since the light extraction efficiency of the color conversion layer has certain limitations, the external quantum efficiency of the color conversion layer also has certain limitations, which cannot meet the efficiency requirement of the display panel.

In some other implementations, there are three methods for alleviating the blue light leakage problem as follows. In the first method, the color conversion material is a quantum dot material, and the problem of blue light leakage is alleviated by increasing the optical density of the quantum dot material. However, when the optical density of the quantum dot material is increased, the dispersion tends to be poor, which results in a decrease in quantum yield (QY). Moreover, the quantum dot material with high optical density may lead to the reduction of the optical conversion efficiency. The second method is to provide a color filter containing dye on a light exit side of the color conversion substrate to absorb the leaked blue light to improve the display contrast. However, in this method, the blue light absorbed by the color filter are wasted and difficult to be effectively utilized. The third method is to mix scattering particles such as TiO₂ and SiO₂ into the color conversion layer to increase the utilization rate of the first color light (e.g., blue light). However, the mixed quantum dots and inorganic scattering particles have problems such as prone to aggregation and quenching, self-absorption and poor stability.

In view of this, as shown in FIGS. 1 and 2, some embodiments of the present disclosure provide a color conversion substrate 100. The color conversion substrate 100 includes a substrate 110, a color conversion layer 120 and a cholesteric liquid crystal layer 130. The color conversion layer 120 is located on a side of the substrate 110; the color conversion layer 120 includes a first color conversion portion 121; the first color conversion portion 121 is configured to convert the first color light L1 incident on the first color conversion portion 121 into the second color light L2. The cholesteric liquid crystal layer 130 includes a first cholesteric liquid crystal unit 131 located between the substrate 110 and the first color conversion portion 121; the first cholesteric liquid crystal unit 131 is configured to reflect unconverted light in the first color light L1 back to the first color conversion portion 121.

In some examples, the substrate 110 may be made of an insulating material such as glass, plastic, quartz, or resin. A material of the substrate 110 may be selected from materials having excellent mechanical strength, thermal stability, transparency, and surface smoothness, and ease of processing, and waterproofness.

For example, the light transmittance of the substrate 110 is greater than or equal to 99.5%. For example, the light transmittance of the substrate 110 may be 99.5%, 99.6%, 99.7%, 99.8% or 99.9%. In this way, the light (e.g., the second color light L2 or the third color light L3) converted by the color conversion layer 120 and the first color light L1 emitted from the first sub-pixel region AA may be emitted from the substrate 110, so that the light extraction efficiency is improved.

For example, the refractive index of the substrate 110 is less than or equal to 1.30. For example, the refractive index of the substrate 110 may be 1.10, 1.15, 1.20, 1.25, or 1.30. In this way, the light (e.g., the second color light L2 or the third color light L3) converted by the color conversion layer 120 and the first color light L1 emitted from the first sub-pixel region AA may be prevented from being reflected at the substrate 110, so that the light extraction efficiency is improved.

In the color conversion substrate 100, as shown in FIG. 2, the color conversion layer 120 is a film layer in the color conversion substrate 100 that realizes the color conversion function. The first color conversion portion 121 may be a portion of the color conversion layer 120 located in the second sub-pixel region BB and may contain a color conversion material corresponding to the second color. In this way, the first color light L1 directed toward the first color conversion portion 121 may be converted into the second color light L2. For example, the first color light L1 is blue light, and the second color light L2 is red light.

For example, the thickness of the first color conversion portion 121 may be in a range of 8 μm to 12 μm, inclusive. For example, the thickness of the first color conversion portion 121 may be 8 μm, 9 μm, 10 μm, 11 μm or 12 μm.

In the related art, the cholesteric liquid crystal (CLC) is a one-dimensional photonic crystal, which is different from other nematic or smectic liquid crystal materials. The cholesteric liquid crystal molecules are flat and arranged in layers, the molecules in a layer are parallel to each other, and the long axis of the molecules is parallel to the layer plane. The direction of the long axis of the molecules in different layers varies slightly, and the long axis of the molecules in different layers are arranged in a helical structure in the normal direction of the layers. Due to the unique helically twisted structure, the cholesteric liquid crystal has special optical properties such as optical activity and selective reflection, and cholesteric liquid crystals with different pitches have different reflection wavelength bands (also referred to as reflection windows), so that the cholesteric liquid crystals can selectively reflect light with a wavelength within their reflection wavelength band and transmit light with a wavelength out of their reflection wavelength band. Therefore, cholesteric liquid crystals that reflect red light, cholesteric liquid crystals that reflect green light, or cholesteric liquid crystals that reflect blue light may be produced separately. In the color conversion substrate 100, as shown in FIG. 2, the material of the cholesteric liquid crystal layer 130 may include cholesteric liquid crystals that reflect the first color light L1, so that the first color light L1 may be reflected. The first color light L1 is, for example, blue light.

It will be understood that, as shown in FIG. 2, since the first cholesteric liquid crystal unit 131 is located between the substrate 110 and the first color conversion portion 121, in a case where the material of the first cholesteric liquid crystal unit 131 includes cholesteric liquid crystals that reflect the first color light L1, the first color light L1 that passes through the first color conversion portion 121 but is not converted may be reflected back to the first color conversion portion 121 by the first cholesteric liquid crystal unit 131, excite the color conversion material in the first color conversion portion 121, and be converted into the second color light L2. In this way, firstly, the first color light L1 leaked from the second sub-pixel region BB may be reduced, so that the color purity of the second color light L2 emitted from the second sub-pixel region BB is relatively high, which may improve the color purity of the display panel 1000, and avoid interference caused by a case that the leaked first color light L1 enters adjacent sub-pixel regions to widen the color gamut; secondly, the light extraction efficiency of the first color conversion portion 121 in the color conversion layer 120 may be improved, so that the external quantum efficiency of the color conversion layer 120 is improved.

In some embodiments, the material of the first color conversion portion 121 includes a first quantum dot material.

It will be understood that the quantum dot material has the advantages of high brightness, high color volume and high efficiency. In a case where the material of the first color conversion portion 121 includes the first quantum dot material, the first quantum dot material may be excited by the first color light L1 to emit the second color light L2, and the emitted second color light L2 has a relatively high brightness, so that the display effect of the display panel 1000 may be improved.

For example, the first quantum dot material may be cadmium selenide (CdSe), cadmium selenide/zinc sulfide (CdSe/ZnS), indium phosphide (InP), copper indium sulfide (CuInS₂, CIS), silver indium sulfide (AgInS₂, AIS), silver gallium sulfide (AgGaS₂, AGS) or a perovskite-based quantum dot material. CdSe/ZnS is a quantum dot material with CdSe as the core and ZnS as the shell.

For example, the peak wavelength of the photoluminescence spectrum of the first quantum dot material may be in a range of 625 nm to 645 nm, inclusive; for example, the peak wavelength of the photoluminescence spectrum of the first quantum dot material may be 625 nm, 630 nm, 635 nm, 640 nm or 645 nm. In this case, the light (i.e., the second color light L2) emitted by the first quantum dot material is red light.

For example, the full width at half maxima (FWHM) of the photoluminescence spectrum of the first quantum dot material may be in a range of 15 nm to 35 nm, inclusive; for example, the full width at half maxima (FWHM) of the photoluminescence spectrum of the first quantum dot material may be 15 nm, 20 nm, 25 nm, 30 nm or 35 nm. In this way, the color purity of the second color light L2 converted by the first quantum dot material may be improved.

For example, the color coordinate CIEx of the light emitted by the first quantum dot material may be in a range of 0.685 to 0.710, inclusive; for example, the color coordinate CIEx of the light emitted by the first quantum dot material may be 0.685, 0.690, 0.695, 0.700, 0.705 or 0.710. In this case, the light (i.e., the second color light L2) emitted by the first quantum dot material is red light. It will be noted that the color coordinate CIEx refers to the color coordinate in the CIE chromaticity diagram. The CIE chromaticity diagram is a color system created by International Commission on Illumination (CIE). In this color system, color attribute may be expressed by chromaticity coordinates CIEx and CIEy.

In some examples, the material of the first color conversion portion 121 further includes a first light-transmitting body material, the first light-transmitting body material is, for example, a light-transmitting adhesive, and the first quantum dot material is dispersed in the first light-transmitting body material. Moreover, the doping amount of the first quantum dot material is in a range of 20 wt % to 50 wt %, inclusive; for example, the doping amount of the first quantum dot material may be 20 wt %, 30 wt %, 42 wt % or 50 wt %.

In some embodiments, as shown in FIGS. 1 and 2, the color conversion layer 120 further includes a second color conversion portion 122 arranged in a first direction X with the first color conversion portion 121. The first direction X intersects with a thickness direction Y of the substrate 110. The second color conversion portion 122 is configured to convert first color light L1 directed toward the second color conversion portion 122 into third color light L3. The cholesteric liquid crystal layer 130 further includes a second cholesteric liquid crystal unit 132 located between the substrate 110 and the second color conversion portion 122; and the second cholesteric liquid crystal unit 132 is configured to reflect unconverted light in the first color light L1 back to the second color conversion portion 122.

The second color conversion portion 122 may be a portion of the color conversion layer 120 located in the third sub-pixel region CC and may contain a color conversion material corresponding to the third color. In this way, the first color light L1 directed toward the second color conversion portion 122 may be converted into the third color light L3. For example, the first color light L1 is blue light, and the third color light L3 is green light.

It will be understood that, as shown in FIG. 2, since the second cholesteric liquid crystal unit 132 is located between the substrate 110 and the second color conversion portion 122, in a case where the material of the second cholesteric liquid crystal unit 132 includes cholesteric liquid crystals that reflect the first color light L1, the first color light L1 that passes through the second color conversion portion 122 but is not converted may be reflected back to the second color conversion portion 122 by the second cholesteric liquid crystal unit 132, excite the color conversion material in the second color conversion portion 122, and be converted into the third color light L3. In this way, firstly, the first color light L1 leaked from the third sub-pixel region CC may be reduced, so that the color purity of the third color light L3 emitted from the third sub-pixel region CC is relatively high, which may improve the color purity of the display panel 1000, and avoid interference caused by a case that the leaked first color light L1 enters adjacent sub-pixel regions to widen the color gamut; secondly, the light extraction efficiency of the second color conversion portion 122 of the color conversion layer 120 may be improved, so that the external quantum efficiency of the color conversion layer 120 is improved.

For example, the thickness of the second color conversion portion 122 may be in a range of 8 μm to 12 μm, inclusive; for example, the thickness of the second color conversion portion 122 may be 8 μm, 9 μm, 10.5 μm, 11 μm or 12 μm. Furthermore, the thickness of the second color conversion portion 122 and the thickness of the first color conversion portion 121 may be the same or different.

In some examples, referring to FIGS. 1 and 2, the second cholesteric liquid crystal unit 132 and the first cholesteric liquid crystal unit 131 may be arranged in the first direction X; moreover, a thickness H2 of the second cholesteric liquid crystal unit 132 and a thickness H1 of the first cholesteric liquid crystal unit 131 may be the same or different.

For example, as shown in FIG. 1, the first direction X is perpendicular to the thickness direction Y of the substrate 110.

In some embodiments, a material of the second color conversion portion 122 includes a second quantum dot material.

It will be understood that the quantum dot material has the advantages of high brightness, high color volume and high efficiency. In a case where the material of the second color conversion portion 122 includes the second quantum dot material, the second quantum dot material may be excited by the first color light L1 to emit the third color light L3, and the emitted third color light L3 has relatively high brightness, so that the display effect of the display panel 1000 may be improved.

For example, the second quantum dot material may be CdSe, CdSe/ZnS, InP, CuInS₂ (CIS), AgInS₂ (AIS), AgGaS₂ (AGS) or a perovskite-based quantum dot material.

For example, the peak wavelength of the photoluminescence spectrum of the second quantum dot material may be in a range of 525 nm to 540 nm, inclusive; for example, the peak wavelength of the photoluminescence spectrum of the second quantum dot material may be 525 nm, 530 nm, 535 nm or 540 nm. In this case, the light (i.e., the third color light L3) emitted by the second quantum dot material is green light.

For example, the full width at half maxima (FWHM) of the photoluminescence spectrum of the second quantum dot material may be in a range of 15 nm to 35 nm, inclusive; for example, the full width at half maxima (FWHM) of the photoluminescence spectrum of the second quantum dot material may be 15 nm, 22 nm, 25 nm, 31 nm or 35 nm. In this way, the color purity of the third color light L3 converted by the second quantum dot material may be improved.

For example, the color coordinate CIEx of the light emitted by the second quantum dot material may be in a range of 0.170 to 0.230, inclusive; for example, the color coordinate CIEx of the light emitted by the second quantum dot material may be 0.170, 0.180, 0.190, 0.200, 0.205, 0.210, 0.220 or 0.230. In this case, the light (i.e., the third color light L3) emitted by the second quantum dot material is green light.

In some examples, the material of the second color conversion portion 122 further includes a second light-transmitting body material, and the second light-transmitting material is, for example, a light-transmitting adhesive, and the second quantum dot material is dispersed in the second light-transmitting body material. Moreover, the doping amount of the second quantum dot material is in a range of 20 wt % to 50 wt %, inclusive; for example, the doping amount of the second quantum dot material may be 20 wt %, 33 wt %, 40 wt % or 50 wt %.

In the related art, the cholesteric liquid crystals have two zero field stable states, one of which is a planar state, which may also be referred to as a planar texture state. Due to the action of a zero electric field, the cholesteric liquid crystals in the planar state have a periodical helical structure, and the helical axis is substantially perpendicular to a surface of a substrate (e.g., the substrate 110). The cholesteric liquid crystals in the planar state have a good reflective property and may reflect light in a set wavelength band. Therefore, the cholesteric liquid crystals in the planar state may exhibit the performance of distributed Bragg reflector (DBR).

In some embodiments, as shown in FIG. 3, the cholesteric liquid crystals in the first cholesteric liquid crystal unit 131 are in a planar state.

It will be understood that, in a case where the cholesteric liquid crystals in the first cholesteric liquid crystal unit 131 are in a planar state, the first cholesteric liquid crystal unit 131 may perform Bragg reflection and have relatively good reflection performance, and it is possible to adjust the pitch of the cholesteric liquid crystals in the first cholesteric liquid crystal unit 131 to make the first cholesteric liquid crystal unit 131 reflect the first color light L1. In this way, the first color light L1 that passes through the first color conversion portion 121 but is not converted may be reflected back to the first color conversion portion 121 by the first cholesteric liquid crystal unit 131, excite the color conversion material in the first color conversion portion 121, and be converted into the second color light L2. Thus, it is possible to reduce the first color light L1 leaked from the second sub-pixel region BB, so that the color purity of the second color light L2 emitted from the second sub-pixel region BB is relatively high, and it is possible to avoid the interference caused by a case that the leaked first color light L1 enters adjacent sub-pixel regions, so as to widen the color gamut; moreover, it is possible to improve the light extraction efficiency of the first color conversion portion 121 of the color conversion layer 120.

In some embodiments, as shown in FIG. 3, the cholesteric liquid crystals in the second cholesteric liquid crystal unit 132 are in a planar state.

It will be understood that, in a case where the cholesteric liquid crystals in the second cholesteric liquid crystal unit 132 are in a planar state, the second cholesteric liquid crystal unit 132 may perform Bragg reflection and have relatively good reflection performance, and it is possible to adjust the pitch of the cholesteric liquid crystal in the second cholesteric liquid crystal unit 132 to make the second cholesteric liquid crystal unit 132 reflect the first color light L1. In this way, the first color light L1 that passes through the second color conversion portion 122 but is not converted may be reflected back to the second color conversion portion 122 by the second cholesteric liquid crystal unit 132, excite the color conversion material in the second color conversion portion 122, and be converted into the third color light L3. Thus, it may be possible to reduce the first color light L1 leaked from the third sub-pixel region CC, so that the color purity of the third color light L3 emitted from the third sub-pixel region CC is relatively high, and it is possible to avoid the interference caused by a case that the leaked first color light L1 enters adjacent sub-pixel regions, so as to widen the color gamut; moreover, it is possible to improve the light extraction efficiency of the second color conversion portion 122 of the color conversion layer 120.

In some implementations, due to the emission characteristic of isotropic of the color conversion material (e.g., the quantum dot material), the second color light and the third color light converted by the color conversion layer have a relatively wide angular distribution, while the angular distribution of the first color light that has not been converted is determined by the optical properties of the light-emitting substrate. In a case where the light-emitting substrate is an organic light-emitting diode (OLED) light-emitting substrate or other types of light-emitting substrate, in the emitted first color light, the amount of light that near the front viewing angle is relatively great, so that the first color light L1 has a relatively narrow angular distribution, which results in a problem of angular color shift due to unmatched angular distributions of light emitted from the first sub-pixel region, the second sub-pixel region, and the third sub-pixel region.

In some embodiments, as shown in FIGS. 1 and 2, the color conversion substrate 100 further includes a light-transmitting portion 140 arranged in the first direction X with the color conversion layer 120. The first direction X intersects with the thickness direction of the substrate 110. The first color light L1 passes through the light-transmitting portion 140. The cholesteric liquid crystal layer 130 further includes a third cholesteric liquid crystal unit 133 located between the substrate 110 and the light-transmitting portion 140; and the third cholesteric liquid crystal unit 133 is configured to scatter a part, near the front viewing angle, of the first color light L1 passing through the light-transmitting portion 140 toward a large viewing angle direction.

The light-transmitting portion 140 and the color conversion portions are arranged in the first direction X. For example, as shown in FIG. 1, the light-transmitting portion 140 may be substantially flush with the color conversion portions in the first direction X, so that the surface of the color conversion substrate 100 may be relatively flat. Moreover, the light-transmitting portion 140 may be located directly opposite to the first sub-pixel region AA, so that the first color light L1 may pass through the light-transmitting portion 140 and be emitted from the first sub-pixel region AA.

For example, a material of the light-transmitting portion 140 may be a transparent photoresist.

For example, a thickness of the light-transmitting portion 140 may be in a range of 8 μm to 12 μm, inclusive; for example, the thickness of the light-transmitting portion 140 may be 8 μm, 9 μm, 10.2 μm, 11.2 μm, or 12 μm. Furthermore, the thickness of the light-transmitting portion 140 and the thickness of the color conversion layer 120 may be the same or different.

It will be understood that, in a case where the third cholesteric liquid crystal unit 133 is disposed between the substrate 110 and the light-transmitting portion 140, and the third cholesteric liquid crystal unit 133 scatters the part of the first color light L1 near the front viewing angle toward the large viewing angle, the angular distribution of the first color light L1 emitted from the first sub-pixel region AA is relatively wide in comparison with the case where the third cholesteric liquid crystal unit 133 is not provided. In this way, the matching of the angular distributions of the light output from the first sub-pixel region AA, the second sub-pixel region BB and the third sub-pixel region CC may be improved, and the problem of angular color shift may be alleviated.

In the related art, the second zero field stable state of the cholesteric liquid crystals is a focal conic state, which may also be referred to as a focal conic texture state. The cholesteric liquid crystals in the focal conic state are of a structure of multi-domain, and the helical structure still exists in each domain. Therefore, the cholesteric liquid crystals in the focal conic state scatter the incident light. Moreover, cholesteric liquid crystals in the focal conic state do not rely on the polarization property of the incident light.

In some embodiments, as shown in FIG. 4, the cholesteric liquid crystals in the third cholesteric liquid crystal unit 133 are in a focal conic state.

It will be understood that, in a case where the cholesteric liquid crystals in the third cholesteric liquid crystal unit 133 are in a focal conic state, it is equivalent to adding scattering particles into the third cholesteric liquid crystal unit 133, so that the third cholesteric liquid crystal unit 133 may scatter the first color light L1 to shape the emission spectrum of the first color light L1. In this way, the angular distribution of the first color light L1 emitted from the first sub-pixel region AA may be relatively wide, so that the matching of the angular distributions of the light output from the first sub-pixel region AA, the second sub-pixel region BB and the third sub-pixel region CC may be improved, and the problem of angular color shift may be alleviated.

The concepts of the helical direction and the pitch of liquid crystal molecules in the cholesteric liquid crystals are explained below. In the related art, the helical structure of the cholesteric liquid crystals is left-handed or right-handed. According to the rotation direction of the helical structure, cholesteric liquid crystals may be divided into left-handed cholesteric liquid crystals and right-handed cholesteric liquid crystals. The cholesteric liquid crystals contain multiple layers of molecules, the arrangement directions of molecules in each layer are the same, but the arrangement directions of two adjacent layers of molecules are slightly rotated, and the multiple layers of molecules are stacked layer by layer into a helical structure. In a case where the arrangement of the molecules rotates 360 degrees and returns to the original direction, the distance between two layers with exactly the same molecular arrangement is referred to as the pitch of the cholesteric liquid crystals. According to actual needs, chiral agents may be added into the cholesteric liquid crystals to change the pitch. If the wavelength of the incident light is consistent with the pitch of the cholesteric liquid crystals, the cholesteric liquid crystals allow the incident light with the opposite rotation direction to pass through and reflect the incident light with the same rotation direction. If the wavelength of the incident light is inconsistent with the pitch of the cholesteric liquid crystals, the cholesteric liquid crystals allow all the incident light to pass through. Therefore, the reflection or transmission of incident light may be changed by adjusting the pitch.

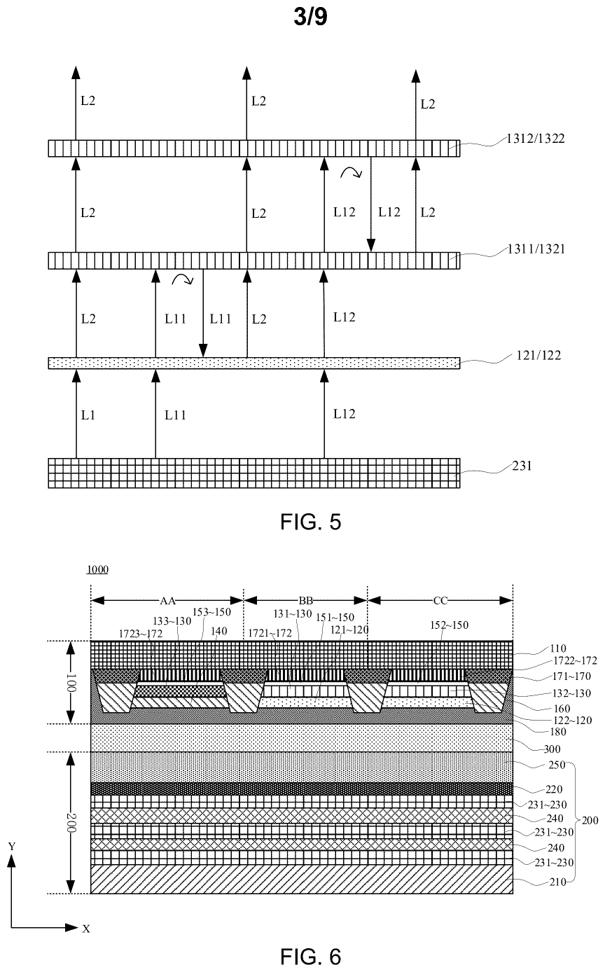

In some embodiments, as shown in FIG. 5, the first cholesteric liquid crystal unit 131 includes a first chiral liquid crystal unit 1311 and a second chiral liquid crystal unit 1312 that are stacked. The helical direction of the liquid crystal molecules in the first chiral liquid crystal unit 1311 is opposite to the helical direction of the liquid crystal molecules in the second chiral liquid crystal unit 1312.

It will be understood that, since the first cholesteric liquid crystal unit 131 can reflect the first color light L1, the pitch of the cholesteric liquid crystals in the first cholesteric liquid crystal unit 131 is consistent with the wavelength of the first color light L1; that is, the pitch of the first chiral liquid crystal unit 1311 and the pitch the second chiral liquid crystal unit 1312 are consistent with the wavelength of the first color light L1. In this way, as shown in FIG. 5, a part of light L11 in the first color light L1, whose rotation direction is the same as the helical direction of the liquid crystal molecules in the first chiral liquid crystal unit 1311, may be reflected back to the first color conversion portion 121 by the first chiral liquid crystal unit 1311 and converted into the second color light L2; moreover, since the helical direction of the liquid crystal molecules in the first chiral liquid crystal unit 1311 is opposite to the helical direction of the liquid crystal molecules in the second chiral liquid crystal unit 1312, a part of light L12 in the first color light L1, whose rotation direction is opposite to the helical direction of the liquid crystal molecules in the first chiral liquid crystal unit 1311, may be reflected back to the first color conversion portion 121 by the second chiral liquid crystal unit 1312 and converted into the second color light L2. In this way, the reflection ability of the first cholesteric liquid crystal unit 131 to the first color light L1 may be improved, so that the first color light L1 leaking from the second sub-pixel region BB is relatively less, and the color purity of the second color light L2 emitted from the second sub-pixel region BB is relatively high; meanwhile, the light extraction efficiency of the first color conversion portion 121 of the color conversion layer 120 may be improved.

In some examples, the helical direction of the liquid crystal molecules in the first chiral liquid crystal unit 1311 is left-handed, and in this case, the helical direction of the liquid crystal molecules in the second chiral liquid crystal unit 1312 is right-handed. In some other examples, the helical direction of the liquid crystal molecules in the first chiral liquid crystal unit 1311 is right-handed, and in this case, the helical direction of the liquid crystal molecules in the second chiral liquid crystal unit 1312 is left-handed.

It will be noted that, a portion of the first cholesteric liquid crystal unit 131 proximate to the first color conversion portion 121 may be the first chiral liquid crystal unit 1311 or the second chiral liquid crystal unit 1312, which is not limited here.

In some embodiments, as shown in FIG. 5, in a case where the cholesteric liquid crystal layer 130 further includes the second cholesteric liquid crystal unit 132, the second cholesteric liquid crystal unit 132 includes a third chiral liquid crystal unit 1321 and a fourth chiral liquid crystal unit 1322 that are stacked. The helical direction of the liquid crystal molecules in the third chiral liquid crystal unit 1321 is opposite to the helical direction of the liquid crystal molecules in the fourth chiral liquid crystal unit 1322.

It will be understood that, since the second cholesteric liquid crystal unit 132 can reflect the first color light L1, the pitch of the cholesteric liquid crystals in the second cholesteric liquid crystal unit 132 is consistent with the wavelength of the first color light L1; that is, the pitch of the third chiral liquid crystal unit 1321 and the pitch the fourth chiral liquid crystal unit 1322 are consistent with the wavelength of the first color light L1. In this way, as shown in FIG. 5, a part of light L11 in the first color light L1, whose rotation direction is the same as the helical direction of the liquid crystal molecules in the third chiral liquid crystal unit 1321, may be reflected back to the second color conversion portion 122 by the third chiral liquid crystal unit 1321 and converted into the third color light L3; moreover, since the helical direction of the liquid crystal molecules in the third chiral liquid crystal unit 1321 is opposite to the helical direction of the liquid crystal molecules in the fourth chiral liquid crystal unit 1322, a part of light L12 in the first color light L1, whose rotation direction is opposite to the helical direction of the liquid crystal molecules in the third chiral liquid crystal unit 1321, may be reflected back to the second color conversion portion 122 by the fourth chiral liquid crystal unit 1322 and converted into the third color light L3. In this way, the reflection ability of the second cholesteric liquid crystal unit 132 to the first color light L1 may be improved, so that the first color light L1 leaking from the third sub-pixel region CC is relatively less, and the color purity of the third color light L3 emitted from the third sub-pixel region CC is relatively high; meanwhile, the light extraction efficiency of the second color conversion portion 122 of the color conversion layer 120 may be improved.

In some examples, the helical direction of the liquid crystal molecules in the third chiral liquid crystal unit 1321 is left-handed, and in this case, the helical direction of the liquid crystal molecules in the fourth chiral liquid crystal unit 1322 is right-handed. In some other examples, the helical direction of the liquid crystal molecules in the third chiral liquid crystal unit 1321 is right-handed, and in this case, the helical direction of the liquid crystal molecules in the fourth chiral liquid crystal unit 1322 is left-handed.

It will be noted that a portion of the second cholesteric liquid crystal unit 132 proximate to the second color conversion portion 122 may be the third chiral liquid crystal unit 1321 or the fourth chiral liquid crystal unit 1322, which is not limited here.

In some embodiments, the pitch of the liquid crystal molecules in the first cholesteric liquid crystal unit 131 is greater than or equal to 270 nm and less than or equal to 310 nm.

It will be understood that, in a case where the pitch of the liquid crystal molecules in the first cholesteric liquid crystal unit 131 is in the range of 270 nm to 310 nm, the wavelength of the light that can be reflected by the first cholesteric liquid crystal unit 131 matches the wavelength of blue light. In this way, the blue light leaked from the second sub-pixel region BB may be reflected back to the first color conversion portion 121 by the first cholesteric liquid crystal unit 131 and converted into the second color light L2 (e.g., red light) by the first color conversion portion 121, so that the color purity of the second color light L2 emitted from the second sub-pixel region BB is relatively high, and the light extraction efficiency of the first color conversion portion 121 of the color conversion layer 120 may be improved.

For example, the pitch of the liquid crystal molecules in the first cholesteric liquid crystal unit 131 may be 270 nm, 280 nm, 290 nm, 300 nm, or 310 nm.

In some embodiments, the pitch of the liquid crystal molecules in the second cholesteric liquid crystal unit 132 is greater than or equal to 270 nm and less than or equal to 310 nm.

It will be understood that, in a case where the pitch of the liquid crystal molecules in the second cholesteric liquid crystal unit 132 is in the range of 270 nm to 310 nm, the wavelength of the light that can be reflected by the second cholesteric liquid crystal unit 132 matches the wavelength of blue light. In this way, the blue light leaked from the third sub-pixel region CC may be reflected back to the second color conversion portion 122 by the second cholesteric liquid crystal unit 132 and converted into the third color light L3 (e.g., green light) by the second color conversion portion 122, so that the color purity of the third color light L3 emitted from the third sub-pixel region CC is relatively high, and the light extraction efficiency of the second color conversion portion 122 of the color conversion layer 120 may be improved.

For example, the pitch of the liquid crystal molecules in the second cholesteric liquid crystal unit 132 may be 270 nm, 278 nm, 291 nm, 300 nm, or 310 nm.

In some embodiments, the first color light L1 is blue light. The central reflection wavelength of the first cholesteric liquid crystal unit 131 is greater than or equal to 450 nm and less than or equal to 470 nm.

It will be understood that, in a case where the central reflection wavelength of the first cholesteric liquid crystal unit 131 is in the range of 450 nm to 470 nm, the wavelength corresponding to the trough of the transmission spectrum of the first cholesteric liquid crystal unit 131 is in the range of 450 nm to 470 nm, which means that the first cholesteric liquid crystal unit 131 may reflect light with a wavelength in the range of 450 nm to 470 nm. In this way, the blue light leaked from the second sub-pixel region BB may be reflected back to the first color conversion portion 121 by the first cholesteric liquid crystal unit 131 and converted into the second color light L2 (e.g., red light) by the first color conversion portion 121, so that the color purity of the second color light L2 emitted from the second sub-pixel region BB is relatively high, and the light extraction efficiency of the first color conversion portion 121 of the color conversion layer 120 may be improved.

For example, the central reflection wavelength of the first cholesteric liquid crystal unit 131 may be 450 nm, 455 nm, 460 nm, 465 nm, or 470 nm.

In some embodiments, the first color light L1 is blue light. The central reflection wavelength of the second cholesteric liquid crystal unit 132 is greater than or equal to 450 nm and less than or equal to 470 nm.

It will be understood that, in a case where the central reflection wavelength of the second cholesteric liquid crystal unit 132 is in the range of 450 nm to 470 nm, the wavelength corresponding to the trough of the transmission spectrum of the second cholesteric liquid crystal unit 132 is in the range of 450 nm to 470 nm, which means that the second cholesteric liquid crystal unit 132 reflects light with a wavelength in the range of 450 nm to 470 nm. In this way, the blue light leaked from the third sub-pixel region CC may be reflected back to the second color conversion portion 122 by the second cholesteric liquid crystal unit 132 and converted into the third color light L3 (e.g., green light) by the second color conversion portion 122, so that the color purity of the third color light L3 emitted from the third sub-pixel region CC is relatively high, and the light extraction efficiency of the second color conversion portion 122 of the color conversion layer 120 may be improved.

For example, the central reflection wavelength of the second cholesteric liquid crystal unit 132 may be 450 nm, 454 nm, 460 nm, 466 nm, or 470 nm.

In some embodiments, the full width at half maxima of the transmission spectrum of the first cholesteric liquid crystal unit 131 is greater than or equal to 70 nm and less than or equal to 100 nm.

It will be understood that, in a case where the full width at half maxima of the transmission spectrum of the first cholesteric liquid crystal unit 131 is in the range of 70 nm to 100 nm, the trough of the transmission spectrum of the first cholesteric liquid crystal unit 131 is relatively narrow. In this way, the first cholesteric liquid crystal unit 131 may specifically reflect the first color light L1 (e.g., blue light) and reflect relatively less light of other wavelength bands or other colors, which may avoid the loss of light of other wavelength bands or other colors during multiple reflections, so that the light extraction efficiency of the first color conversion portion 121 of the color conversion layer 120 is improved.

For example, the full width at half maxima of the transmission spectrum of the first cholesteric liquid crystal unit 131 may be 70 nm, 80 nm, 90 nm, or 100 nm. In some embodiments, the full width at half maxima of the transmission spectrum of the second cholesteric liquid crystal unit 132 is greater than or equal to 70 nm and less than or equal to 100 nm.

It will be understood that, in a case where the full width at half maxima of the transmission spectrum of the second cholesteric liquid crystal unit 132 is in the range of 70 nm to 100 nm, the trough of the transmission spectrum of the second cholesteric liquid crystal unit 132 is relatively narrow. In this way, the second cholesteric liquid crystal unit 132 may specifically reflect the first color light L1 (e.g., blue light) and reflect relatively less light of other wavelength bands or other colors, which may avoid the loss of light of other wavelength bands or other colors during multiple reflections, so that the light extraction efficiency of the second color conversion portion 122 in the color conversion layer 120 is improved.

For example, the full width at half maxima of the transmission spectrum of the second cholesteric liquid crystal unit 132 may be 70 nm, 85 nm, 95 nm, or 100 nm.

In some embodiments, as shown in FIG. 6, the color conversion substrate 100 further includes an alignment layer 150 located between the cholesteric liquid crystal layer 130 and the substrate 110. The alignment layer 150 includes a first alignment portion 151, a second alignment portion 152, and a third alignment portion 153 that are arranged in the first direction X. The first alignment portion 151 is configured to align the liquid crystal molecules in the first cholesteric liquid crystal unit 131. The second alignment portion 152 is configured to align the liquid crystal molecules in the second cholesteric liquid crystal unit 132. The third alignment portion 153 is configured to align the liquid crystal molecules in the third cholesteric liquid crystal unit 133.

The alignment layer 150 is provided between the cholesteric liquid crystal layer 130 and the substrate 110, and the alignment layer 150 is made parallel to the substrate 110. In this way, the initial alignment of the liquid crystal molecules in the first cholesteric liquid crystal unit 131 may be made parallel to the substrate 110 by using the first alignment portion 151, so that the purpose of aligning the liquid crystal molecules in the first cholesteric liquid crystal unit 131 may be achieved; the initial alignment of the liquid crystal molecules in the second cholesteric liquid crystal unit 132 may be made parallel to the substrate 110 by using the second alignment portion 152, so that the purpose of aligning the liquid crystal molecules in the second cholesteric liquid crystal unit 132 may be achieved; the initial alignment of the liquid crystal molecules in the third cholesteric liquid crystal unit 133 may be made parallel to the substrate 110 by using the third alignment portion 153, so that the purpose of aligning the liquid crystal molecules in the third cholesteric liquid crystal unit 133 may be achieved. Thus, the molecular long axis of the liquid crystal molecules in a first initial cholesteric liquid crystal unit 131a, the molecular long axis of the liquid crystal molecules in a second initial cholesteric liquid crystal unit 132a, and the molecular long axis of the liquid crystal molecules in a third initial cholesteric liquid crystal unit 133a may be made parallel to the substrate 110 to form the cholesteric liquid crystal structure. The above alignment principle may be photo-alignment or rubbing-alignment, which is not limited here. For the description of the first initial cholesteric liquid crystal unit 131a, the second initial cholesteric liquid crystal unit 132a, and the third initial cholesteric liquid crystal unit 133a, reference may be made to the following S2.1 in a manufacturing method of the color conversion substrate 100, which will not be repeated here.

For example, a material of the alignment layer 150 may be an alignment agent, such as polyimide.

It will be noted that, in a case where the first cholesteric liquid crystal unit 131 includes the first chiral liquid crystal unit 1311 and the second chiral liquid crystal unit 1312, the first alignment portion 151 may align the liquid crystal molecules in one of the first chiral liquid crystal unit 1311 and the second chiral liquid crystal unit 1312 that is proximate to the substrate 110; in a case where the second cholesteric liquid crystal unit 132 includes the third chiral liquid crystal unit 1321 and the fourth chiral liquid crystal unit 1322, the second alignment portion 152 may align the liquid crystal molecules in one of the third chiral liquid crystal unit 1321 and the fourth chiral liquid crystal unit 1322 that is proximate to the substrate 110.

The above are exemplary descriptions for the first cholesteric liquid crystal unit 131, the second cholesteric liquid crystal unit 132 and the alignment layer 150, and the third cholesteric liquid crystal unit 133 will be exemplarily described below.

In the related art, haze is a percentage of intensity of the transmitted light that deviates from the incident light by more than 2.5° to the total intensity of the transmitted light. The greater the haze, the lower the gloss and transparency of the film, especially the imaging quality.

In some embodiments, the haze of the third cholesteric liquid crystal unit 133 is greater than or equal to 3% and less than or equal to 8%.

It will be understood that, in a case where the haze of the third cholesteric liquid crystal unit 133 is in the range of 3% to 8%, the light extraction efficiency in the front of the third cholesteric liquid crystal unit 133 is relatively high; furthermore, in comparison with the first color light L1 incident on the third cholesteric liquid crystal unit 133, the first color light L1 passing through the third cholesteric liquid crystal unit 133 has a relatively wide angular distribution, so that the matching of the angular distributions of the light output from the first sub-pixel region AA, the second sub-pixel region BB and the third sub-pixel region CC may be improved, and the problem of angular color shift may be alleviated.

For example, the haze of the third cholesteric liquid crystal unit 133 may be 3%, 4%, 5%, 6%, 7% or 8%.

In some embodiments, the transmittance of the third cholesteric liquid crystal unit 133 to the light in a first wavelength band is greater than or equal to 90%. The minimum wavelength of the first wavelength band is 450 nm, and the maximum wavelength of the first wavelength band is 470 nm.

It will be understood that, in a case where the minimum wavelength of the first wavelength band is 450 nm and the maximum wavelength of the first wavelength band is 470 nm, the light in the first wavelength band matches the blue light. In a case where the transmittance of the third cholesteric liquid crystal unit 133 to the light in the first wavelength band is greater than or equal to 90%, the transmittance of the third cholesteric liquid crystal unit 133 to the blue light is relatively high, so that the light extraction efficiency of the third cholesteric liquid crystal unit 133 may be improved, and the color extraction efficiency of the color conversion substrate 100 may be improved.

For example, the transmittance of the third cholesteric liquid crystal unit 133 to the light in the first wavelength band may be 90%, 92%, 94%, 96%, 98%, 99% or 100%.

In some embodiments, as shown in FIG. 2, a thickness H of the cholesteric liquid crystal layer 130 is greater than or equal to 2 μm and less than or equal to 6 μm. It will be understood that, the thickness H of the cholesteric liquid crystal layer 130 is in the range of 2 μm to 6 μm. Thus, firstly, the first cholesteric liquid crystal unit 131 and the second cholesteric liquid crystal unit 132 may have a certain thickness to achieve the function of reflecting the first color light L1. Secondly, it is possible to prevent the cholesteric liquid crystal layer 130 from absorbing a relatively large amount of incident light. In a case where the thickness H1 of the first cholesteric liquid crystal unit 131 is in the range of 2 μm to 6 μm, it is possible to prevent the first cholesteric liquid crystal unit 131 from absorbing a relatively large amount of light passing through the first color conversion portion 121, such as the second color light L2 generated by conversion and/or the first color light L1 that has not been converted; in a case where the thickness H2 of the second cholesteric liquid crystal unit 132 is in the range of 2 μm to 6 μm, it is possible to prevent the second cholesteric liquid crystal unit 131 from absorbing a relatively large amount of light passing through the second color conversion portion 122, such as the third color light L3 generated by conversion and/or the first color light L1 that has not been converted; in a case where the thickness H3 of the third cholesteric liquid crystal unit 133 is in the range of 2 μm to 6 μm, it is possible to prevent the third cholesteric liquid crystal unit 133 from absorbing a relatively large amount of light (i.e., the first color light L1) that passes through the light-transmitting portion 140; thus, the color extraction efficiency of the color conversion substrate 100 may be relatively high, and the efficiency of the display panel 1000 may be relatively high. Thirdly, in a case where the thickness H of the cholesteric liquid crystal layer 130 is relatively large, the haze of the cholesteric liquid crystal layer 130 is correspondingly relatively high; therefore, in the case where the thickness H of the cholesteric liquid crystal layer 130 is in the range of 2 μm to 6 μm, the haze of the cholesteric liquid crystal layer 130 may be prevented from being relatively high, so that the display panel 1000 may achieve a relatively good display effect.

For example, the thickness H1 of the first cholesteric liquid crystal unit 131 may be 2 μm, 3 μm, 4 μm, 5 μm, or 6 μm.

For example, in the case where the first cholesteric liquid crystal unit 131 includes the first chiral liquid crystal unit 1311 and the second chiral liquid crystal unit 1312 that are stacked, a thickness of the first chiral liquid crystal unit 1311 is greater than or equal to 1 μm and less than or equal to 3 μm, such as 1 μm, 1.3 μm, 2 μm, 2.7 μm or 3 μm; and a thickness of the second chiral liquid crystal unit 1312 is greater than or equal to 1 μm and less than or equal to 3 μm, such as 1 μm, 1.4 μm, 2 μm, 2.5 μm or 3 μm. Furthermore, the thickness of the first chiral liquid crystal unit 1311 and the thickness of the second chiral liquid crystal unit 1312 may be the same or different.

For example, the thickness H2 of the second cholesteric liquid crystal unit 132 may be 2 μm, 3.2 μm, 4 μm, 5.3 μm or 6 μm.

For example, in the case where the second cholesteric liquid crystal unit 132 includes the third chiral liquid crystal unit 1321 and the fourth chiral liquid crystal unit 1322 that are stacked, a thickness of the third chiral liquid crystal unit 1321 is greater than or equal to 1 μm and less than or equal to 3 μm, such as 1 μm, 1.5 μm, 2 μm, 2.5 μm or 3 μm, and a thickness of the fourth chiral liquid crystal unit 1322 is greater than or equal to 1 μm and less than or equal to 3 μm, such as 1 μm, 1.6 μm, 2 μm, 2.4 μm or 3 μm. Furthermore, the thickness of the third chiral liquid crystal unit 1321 and the thickness of the fourth chiral liquid crystal unit 1322 may be the same or different.

For example, the thickness H3 of the third cholesteric liquid crystal unit 133 may be 2 μm, 3 μm, 4.5 μm, 5 μm or 6 μm.

It will be noted that, the thicknesses of any two of the first cholesteric liquid crystal unit 131, the second cholesteric liquid crystal unit 132 and the third cholesteric liquid crystal unit 133 may be the same or different, which is not limited here.

In some examples, the thicknesses of the first cholesteric liquid crystal unit 131, the second cholesteric liquid crystal unit 132 and the third cholesteric liquid crystal unit 133 are the same, so that the first cholesteric liquid crystal unit 131, the second cholesteric liquid crystal unit 132 and the third cholesteric liquid crystal unit 133 may be produced in a single coating process, which may simplify the process.

In some embodiments, as shown in FIGS. 1 and 6, the color conversion substrate 100 further includes a barrier pattern 160. The barrier pattern 160 includes a plurality of first openings Q. The first color conversion portion 121 and the first cholesteric liquid crystal unit 131 are located in a first opening Q. The second color conversion portion 122 and the second cholesteric liquid crystal unit 132 are located in another first opening Q. The light-transmitting portion 140 and the third cholesteric liquid crystal unit 133 are located in yet another first opening Q.

It will be understood that, the barrier pattern 160 may separate the first sub-pixel region AA, the second sub-pixel region BB, and the third sub-pixel region CC. In this way, firstly, the large-angle light emitted from the first sub-pixel region AA, the second sub-pixel region BB, and the third sub-pixel region CC may be absorbed by the barrier pattern 160, so that the cross-color between adjacent sub-pixel regions may be alleviated; secondly, the first color conversion portion 121 and the second color conversion portion 122 may be separated from each other during the producing process, so that the feasibility of the process is improved; thirdly, it is conducive to forming the color conversion layer 120 and the cholesteric liquid crystal layer 130 with a relatively great thickness; the color conversion layer 120 is relatively thick, so that the conversion efficiency of the color conversion layer 120 for the first color light L1 may be improved; the cholesteric liquid crystal layer 130 is relatively thick, so that the reflection effect of the first cholesteric liquid crystal unit 131 and the second cholesteric liquid crystal unit 132 on the first color light L1 may be improved, and the scattering effect of the third cholesteric liquid crystal unit 133 on the first color light L1 may be improved.

In some examples, as shown in FIGS. 1 and 6, a cross section of a portion of the barrier pattern 160 located between two adjacent sub-pixel regions is in a shape of an inverted trapezoid in which a size of one end is larger than a size of the other end and the smaller-sized end is farther away from the substrate 110 than the larger-sized end. In this way, more light emitted from the light-emitting substrate 200 may enter the first sub-pixel region AA, the second sub-pixel region BB and the third sub-pixel region CC.

For example, a thickness of the barrier pattern 160 in a second direction Y may be 5 μm, 10 μm, 15 μm, 18 μm or 20 μm; the second direction Y is the thickness direction of the substrate 110.

For example, a material of the barrier pattern 160 may be an acrylate polymer material or an epoxy polymer material.

In some embodiments, as shown in FIGS. 1 and 6, the color conversion substrate 100 further includes a light-blocking layer 170 located between the cholesteric liquid crystal layer 130 and the substrate. The light-blocking layer 170 includes a light-absorbing pattern 171 and a plurality of color filter portions 172. The light-absorbing pattern 171 includes a plurality of second openings N, and the plurality of second openings N are directly opposite to the plurality of first openings Q. The plurality of color filter portions 172 are located on a side of the substrate proximate to the cholesteric liquid crystal layer 130; a color filter portion 172 is disposed in a second opening N. The plurality of color filter portions 172 include a first color filter portion 1721 directly opposite to the first color conversion portion 121, a second color filter portion 1722 directly opposite to the second color conversion portion 122, and a third color filter portion 1723 directly opposite to the light-transmitting portion 140.

With the design in which the light-blocking layer 170 includes the light-absorbing pattern 171, different color filter portions 172 may be separated, and the light incident on the light-absorbing pattern 171 may be absorbed, so as to improve the display contrast of the display panel 1000. With the arrangement in which the plurality of second openings N are directly opposite to the plurality of first openings Q, the first openings Q and the second openings N may together form sub-pixel regions, such as the first sub-pixel region AA, the second sub-pixel region BB or the third sub-pixel region CC.

For example, a thickness of the light-absorbing pattern 171 in the second direction Y may be 2 μm, 3 μm, 4 μm, 5 μm or 6 μm.

For example, a material of the light-absorbing pattern 171 may be a mixed material of metal, metal oxide and resin. The metal is, for example, chromium; the metal oxide is, for example, chromium oxide.

The color filter portion 172 may be configured to allow the light having the same color as the color thereof to pass through and filter the light having a different color. By providing the first color filter portion 1721, the second color light L2 in the external light may enter the second sub-pixel region BB and be emitted after reflection, thereby increasing the light efficiency; meanwhile, other light except for the second color light L2 in the external light may be filtered to improve the color purity of the light emitted from the second sub-pixel region BB, so that the color gamut of the display panel 1000 may be high.

For example, in a case where the second color light L2 is red light, a material of the first color filter portion 1721 may include photoresist resin, and red dye or red pigment dispersed in the photoresist resin.

For example, a transmittance of the first color filter portion 1721 to red light is greater than or equal to 80%; for example, it may be 80%, 85%, 90% or 99%.

For example, a thickness of the first color filter portion 1721 may be in a range of 1 μm to 3 μm, inclusive; for example, it may be 1 μm, 1.5 μm, 2 μm, 2.5 μm or 3 μm.

By providing the second color filter portion 1722, the third color light L3 in the external light may enter the third sub-pixel region CC and be emitted after reflection, thereby increasing the light efficiency; meanwhile, other light except for the third color light L3 in the external light may be filtered to improve the color purity of the light emitted from the third sub-pixel region CC, so that the color gamut of the display panel 1000 may be high.

For example, in a case where the third color light L3 is green light, a material of the second color filter portion 1722 may include photoresist resin, and green dye or green pigment dispersed in the photoresist resin.

For example, a transmittance of the second color filter portion 1722 to green light is greater than or equal to 75%; for example, it may be 75%, 80%, 90% or 99%.

For example, a thickness of the second color filter portion 1722 may be in a range of 1 μm to 3 μm, inclusive; for example, it may be 1 μm, 1.6 μm, 2 μm, 2.4 μm or 3 μm.

By providing the third color filter portion 1723, the first color light L1 in the external light may enter the first sub-pixel region AA and be emitted after reflection, thereby increasing the light efficiency; meanwhile, other light except for the first color light L1 in the external light may be filtered to improve the color purity of the light emitted from the first sub-pixel region AA, so that the color gamut of the display panel 1000 may be high.

For example, in a case where the first color light L1 is a blue light, a material of the third color filter portion 1723 may include photoresist resin, and blue dye or blue pigment dispersed in the photoresist resin.

For example, a transmittance of the third color filter portion 1723 to blue light is greater than or equal to 70%; for example, it may be 70%, 80%, 90% or 98%.

For example, a thickness of the third color filter portion 1723 may be in a range of 1 μm to 3 μm, inclusive; for example, it may be 1 μm, 1.4 μm, 2 μm, 2.6 μm or 3 μm.

In some embodiments, as shown in FIGS. 1 and 6, the color conversion substrate 100 further includes a first encapsulation layer 180, and the first encapsulation layer 180 is located on a side of the first color conversion portion 121, the second color conversion portion 122, and the light-transmitting portion 140 away from the substrate 110. In the case where the color conversion substrate 100 further includes the barrier pattern 160, the first encapsulation layer 180 is also located on a side of the barrier pattern 160 away from the substrate 110.

With such an arrangement, the first encapsulation layer 180 may be used to cover the first color conversion portion 121, the second color conversion portion 122, the light-transmitting portion 140 and the barrier pattern 160, so as to encapsulate the first color conversion portion 121 and the second color conversion portion 122 to avoid shortening the service life of the color conversion substrate 100 caused by the damage to the material (e.g., a red quantum dot material) of the first color conversion portion 121 and the material (e.g., a green quantum dot material) of the second color conversion portion 122 due to a case that water moisture and oxygen in the external environment enter the color conversion substrate 100.

For example, the first encapsulation layer 180 may include a plurality of first encapsulation sub-layers that are stacked, and a material of the first encapsulation sub-layer may be an organic material or an inorganic material. The organic material is, for example, an acrylic polymer material or an epoxy polymer material. The inorganic material is, for example, silicon oxide (SiOx), silicon nitride (SiNx), or aluminum oxide (Al₂O₃).

For example, a thickness of the first encapsulation layer 180 may be in a range of 10 μm to 30 μm, inclusive; for example, it may be 10 μm, 15 μm, 20 μm, 25 μm or 30 μm.

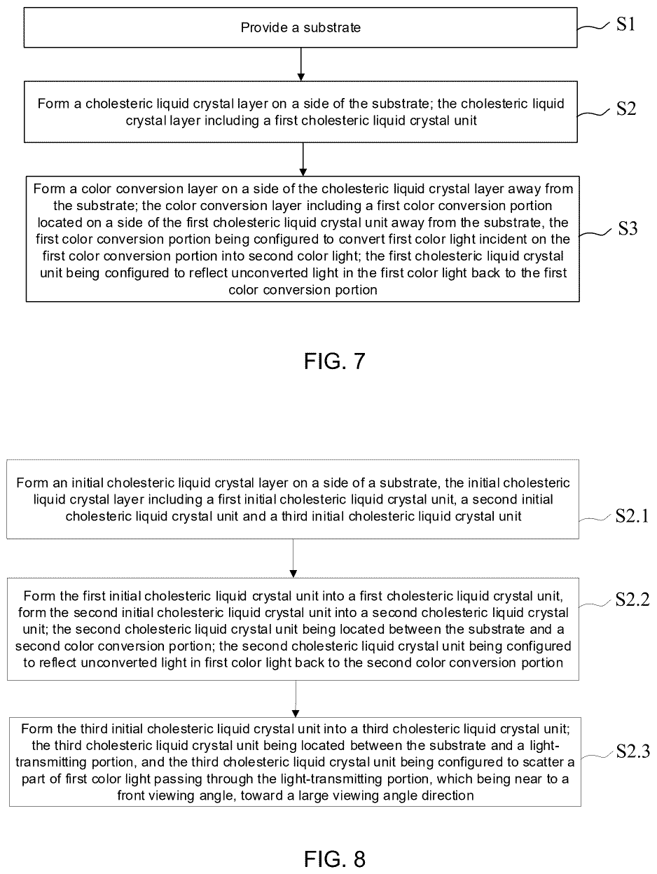

Some embodiments of the present disclosure provide a manufacturing method of a color conversion substrate 100, and as shown in FIG. 7, the manufacturing method includes S1 to S3.

In S1, a substrate 110 is provided.

In S2, a cholesteric liquid crystal layer 130 is formed on a side of the substrate 110; the cholesteric liquid crystal layer 130 includes a first cholesteric liquid crystal unit 131.

In S3, a color conversion layer 120 is formed on a side of the cholesteric liquid crystal layer 130 away from the substrate 110; the color conversion layer 120 includes a first color conversion portion 121 located on a side of the first cholesteric liquid crystal unit 131 away from the substrate 110. The first color conversion portion 121 is configured to convert first color light L1 incident on the first color conversion portion 121 into second color light L2. The first cholesteric liquid crystal unit 131 is configured to reflect unconverted light in the first color light L1 back to the first color conversion portion 121.

The beneficial effects that can be achieved by the manufacturing method of the color conversion substrate 100 provided in some embodiments of the present disclosure are the same as the beneficial effects that can be achieved by color conversion substrate 100 provided in the above technical solutions, and details will not be repeated here.

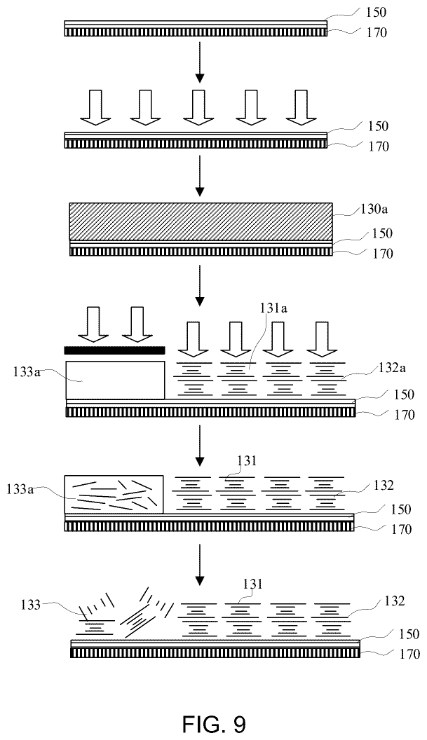

In some embodiments, as shown in FIGS. 8 and 9, forming the cholesteric liquid crystal layer 130 on a side of the substrate 110 includes S2.1 to S2.3.

In S2.1, as shown in FIG. 9, an initial cholesteric liquid crystal layer 130a is formed on a side of the substrate 110, and the initial cholesteric liquid crystal layer 130a includes a first initial cholesteric liquid crystal unit 131a, a second initial cholesteric liquid crystal unit 132a and a third initial cholesteric liquid crystal unit 133a.

For example, the process for forming the initial cholesteric liquid crystal layer 130a is a coating process.

For example, the material for forming the initial cholesteric liquid crystal layer 130a is a precursor material. The precursor material includes, for example, liquid crystal monomers, a chiral additive and a photoinitiator.

For example, in the precursor material, the mass proportion of the liquid crystal monomers may be in a range of 85% to 95%, inclusive; for example, it may be 85%, 88%, 90%, 92% or 95%.

For example, in the precursor material, the mass proportion of the chiral additive may be in a range of 2% to 5%, inclusive; for example, it may be 2%, 3%, 4%, 4.5% or 5%.

For example, in the precursor material, the mass proportion of the photoinitiator may be in a range of 1% to 5%, inclusive; for example, it may be 1%, 2%, 3%, 4% or 5%.

For example, the liquid crystal monomer may be selected from any one of the structures shown in the following general formula (I).

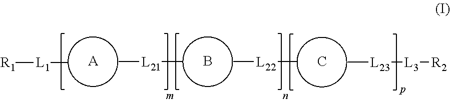

In the general formula (I), R¹ and R² are the same or different, and are independently selected from polymerizable functional groups, such as acrylate groups, vinyl ether groups, thiol groups or epoxy groups. L₁, L₂₁, L₂₂, L₂₃ and L₃ are the same or different, and are independently selected from C0-C20 alkyl groups and alkyl groups containing heteroatoms such as N, O and S, so as to achieve the function of a bridging chain. A, B and C are the same or different, and are independently selected from any one of aryl, heteroaryl and cycloalkane; for example, aryl is phenyl, naphthyl or biphenyl. m, n and p are the same or different, and are independently selected from any one of 0, 1, 2, 3, 4 and 5.

For example, the structure of the liquid crystal monomer may be the structure shown in the structural formula (II).

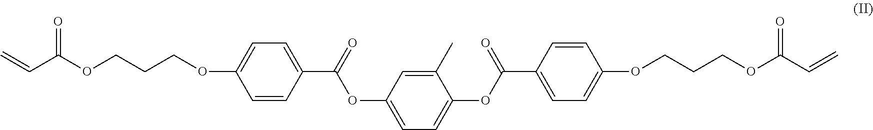 [SMILES: C=CC(=O)OCCCOc1ccc(C(=O)Oc2ccc(OC(=O)c3ccc(OCCCOC(=O)C=C)cc3)c(C)c2)cc1]

For example, the structure of the photoinitiator may be the structure shown in the structural formula (III).

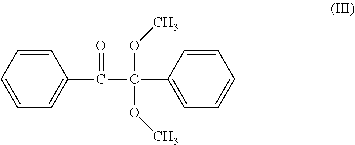 [SMILES: COC(OC)(C(=O)c1ccccc1)c1ccccc1]

It will be noted that, the structural formulas listed above are examples of the structures of the liquid crystal monomers and the photoinitiator, and are not limitations on the liquid crystal monomers and photoinitiator. Moreover, (I), (II) and (III) in the above structural formulas are labels of the structural formulas and are not a part of the structure in the structural formulas.

In S2.2, as shown in FIG. 9, the first initial cholesteric liquid crystal unit 131a is formed into the first cholesteric liquid crystal unit 131, and the second initial cholesteric liquid crystal unit 132a is formed into the second cholesteric liquid crystal unit 132.

In some examples, forming the first initial cholesteric liquid crystal unit 131a into the first cholesteric liquid crystal unit 131, and forming the second initial cholesteric liquid crystal unit 132a into the second cholesteric liquid crystal unit 132, include S2.2.1 to S2.2.3.

In S2.2.1, as shown in FIG. 9, a mask is placed above the initial cholesteric liquid crystal layer 130a to expose the first initial cholesteric liquid crystal unit 131a and the second initial cholesteric liquid crystal unit 132a.

In S2.2.2, as shown in FIG. 9, the first initial cholesteric liquid crystal unit 131a and the second initial cholesteric liquid crystal unit 132a are solidified by using ultraviolet light irradiation to form the first cholesteric liquid crystal unit 131 and the second cholesteric liquid crystal unit 132.

With the above processes, the first initial cholesteric liquid crystal unit 131a and the second initial cholesteric liquid crystal unit 132a irradiated with ultraviolet light may undergo a curing reaction to form the first cholesteric liquid crystal unit 131 and the second cholesteric liquid crystal unit 132 containing cholesteric liquid crystals in a planar state. The liquid crystal molecules in a region (e.g., the third initial cholesteric liquid crystal unit 133a) that is not irradiated by ultraviolet light are still cholesteric liquid crystals in a planar state that are in small molecules, and do not undergo a curing reaction.

For example, the irradiation intensity of the ultraviolet light may be in a range of 0.5 mW/cm² to 10.0 mW/cm², inclusive; for example, it may be 0.5 mW/cm², 2.0 mW/cm², 4.0 mW/cm², 6.0 mW/cm², 8.0 mW/cm² or 10.0 mW/cm².

For example, the irradiation time of the ultraviolet light may be in a range of 2 min to 30 min; for example, it may be 2 min, 10 min, 15 min, 20 min, 25 min or 30 min.

In S2.2.3, the mask is removed.

In S2.3, as shown in FIG. 9, the third initial cholesteric liquid crystal unit 133a is formed into the third cholesteric liquid crystal unit 133.

In some examples, forming the third initial cholesteric liquid crystal unit 133a into the third cholesteric liquid crystal unit 133 includes S2.3.1 to S2.3.2.

In S2.3.1, the third initial cholesteric liquid crystal unit 133a is heated to make the temperature of the third initial cholesteric liquid crystal unit 133a higher than the clearing point of the liquid crystal molecules.

With the above process, the helical axis of the cholesteric liquid crystals in the third initial cholesteric liquid crystal unit 133a may be made isotropic to form cholesteric liquid crystals in a focal conic state.

For example, the third initial cholesteric liquid crystal unit 133a is heated to a temperature in a range of 120° C. to 150° C., inclusive, such as 120° C., 125° C., 130° C., 135° C., 140° C., 145° C. or 150° C., so as to make the temperature of the third initial cholesteric liquid crystal unit 133a higher than the clearing point of the liquid crystal molecules.

In S2.3.2, the third initial cholesteric liquid crystal unit 133a is cooled down under ultraviolet light irradiation to be solidified to form the third cholesteric liquid crystal unit 133.

With the above process, the third initial cholesteric liquid crystal unit 133a irradiated by ultraviolet light may undergo a curing reaction to form the third cholesteric liquid crystal unit 133 containing cholesteric liquid crystals in a focal conic state.

For example, the cooling rate of the third initial cholesteric liquid crystal unit 133a may be in a range of 0.5° C./min to 10.0° C./min, inclusive; for example, it may be 0.5° C./min, 2.0° C./min, 4.0° C./min, 6.0° C./min, 8.0° C./min or 10.0° C./min.

For example, the irradiation intensity of the ultraviolet light may be in a range of 0.5 mW/cm² to 10.0 mW/cm², inclusive; for example, it may be 0.5 mW/cm², 1.5 mW/cm², 4.0 mW/cm², 6.5 mW/cm², 8.0 mW/cm² or 10.0 mW/cm².

It will be noted that, FIG. 9 is a simplified schematic diagram obtained after removing other film layers in the color conversion substrate 100 except for the film layers related to the cholesteric liquid crystal layer 130.

In some embodiments, as shown in FIG. 9, before forming the cholesteric liquid crystal layer 130 on a side of the substrate 110, an alignment layer 150 is formed on the side of the substrate 110. The process of forming the alignment layer 150 is, for example, to first form an initial alignment layer and then perform a photo-alignment process on the initial alignment layer. The process of forming the initial alignment layer is, for example, a coating process.

As shown in FIG. 6, the alignment layer 150 includes a first alignment portion 151, a second alignment portion 152 and a third alignment portion 153 that are arranged in the first direction X. The first alignment portion 151 is configured to align the liquid crystal molecules in the first cholesteric liquid crystal unit 131. The second alignment portion 152 is configured to align the liquid crystal molecules in the second cholesteric liquid crystal unit 132. The third alignment portion 153 is configured to align the liquid crystal molecules in the third cholesteric liquid crystal unit 133.

In some embodiments, the first cholesteric liquid crystal unit 131 includes a first chiral liquid crystal unit 1311 and a second chiral liquid crystal unit 1312, and the second cholesteric liquid crystal unit 132 includes a third chiral liquid crystal unit 1321 and a fourth chiral liquid crystal unit 1322. In this case, forming the cholesteric liquid crystal layer 130 on a side of the substrate 110 includes R1 to R6.

In R1, a first sub-layer in the initial cholesteric liquid crystal layer 130a is formed on the side of the substrate 110, and the first sub-layer of the initial cholesteric liquid crystal layer 130a includes a first sub-unit of the first initial cholesteric liquid crystal unit 131a, a first sub-unit of the second initial cholesteric liquid crystal unit 132a, and a first sub-unit of the third initial cholesteric liquid crystal unit 133a.

For the description of the forming process and materials (e.g., the liquid crystal monomers, the chiral additive and the photoinitiator) in step R1, reference may be made to the description of step S2.1 in steps S2.1 to S2.3 in the aforementioned method, which will not be repeated here.

For example, in the materials for forming the first sub-layer of the initial cholesteric liquid crystal layer 130a, the chiral additive is a first chiral additive, which may be represented by the structure shown in the structural formula (IV).

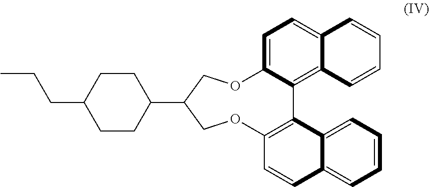

In R2, the first sub-unit of the first initial cholesteric liquid crystal unit 131a is formed into the first chiral liquid crystal unit 1311, and the first sub-unit of the second initial cholesteric liquid crystal unit 132a is formed into the third chiral liquid crystal unit 1321.

For the description of the forming process in step R2, reference may be made to the description of step S2.2 in steps S2.1 to S2.3 in the aforementioned method, which will not be repeated here.

In R3, the first sub-unit of the third initial cholesteric liquid crystal unit 133a is formed into a first sub-unit of the third cholesteric liquid crystal unit 133.

For the description of the forming process in step R3, reference may be made to the description of step S2.3 in steps S2.1 to S2.3 in the aforementioned method, which will not be repeated here.

In R4, a second sub-layer of the initial cholesteric liquid crystal layer 130a is formed on a side of the first chiral liquid crystal unit 1311, the third chiral liquid crystal unit 1321 and the first sub-unit of the third cholesteric liquid crystal unit 133, and the second sub-layer of the initial cholesteric liquid crystal layer 130a includes a second sub-unit of the first initial cholesteric liquid crystal unit 131a, a second sub-unit of the second initial cholesteric liquid crystal unit 132a and a second sub-unit of the third initial cholesteric liquid crystal unit 133a.

For the description of the forming process and materials (e.g., the liquid crystal monomers, the chiral additive and the photoinitiator) in step R4, reference may be made to the description of step S2.1 in steps S2.1 to S2.3 in the aforementioned method, which will not be repeated here.

For example, in the materials for forming the second sub-layer of the initial cholesteric liquid crystal layer 130a, the chiral additive is a second chiral additive, which may be represented by the structure shown in the structural formula (V).

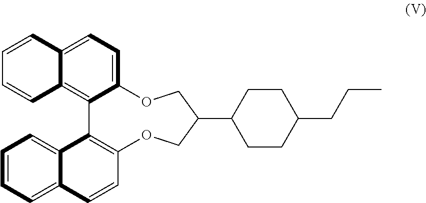

It will be noted that, the structural formulas listed above are examples of the structures of the first chiral additive and the second chiral additive, and are not limitations on the first chiral additive and the second chiral additive. Moreover, (IV) and (V) in the above structural formulas are labels of the structural formulas, and are not a part of the structure in the structural formulas.

In R5, the second sub-unit of the first initial cholesteric liquid crystal unit 131a is formed into the second chiral liquid crystal unit 1312, and the second sub-unit of the second initial cholesteric liquid crystal unit 132a is formed into the fourth chiral liquid crystal unit 1322.

For the description of the forming process in step R5, reference may be made to the description of step S2.2 in steps S2.1 to S2.3 in the aforementioned method, which will not be repeated here.

In R6, the second sub-unit of the third initial cholesteric liquid crystal unit 133a is formed into a second sub-unit of the third cholesteric liquid crystal unit 133.

For the description of the forming process in step R6, reference may be made to the description of step S2.3 in steps S2.1 to S2.3 in the aforementioned method, which will not be repeated here.

It will be noted that, the first sub-unit of the third cholesteric liquid crystal unit 133 and the second sub-unit of the third cholesteric liquid crystal unit 133 together constitute the third cholesteric liquid crystal unit 133.

Some embodiments of the present disclosure provide a display panel 1000. As shown in FIGS. 1 and 6, the display panel 1000 includes the color conversion substrate 100 as described in any one of the above embodiments and a light-emitting substrate 200. The light-emitting substrate 200 is opposite to the color conversion substrate 100; and the light-emitting substrate 200 is configured to emit the first color light L1.

The first color light L1 emitted by the light-emitting substrate 200 is, for example, blue light. By placing the light-emitting substrate 200 opposite to the color conversion substrate 100 in any one of the above embodiments, the color conversion substrate 100 can convert the first color light L1 emitted by the light-emitting substrate 200 and located in the second sub-pixel region BB and the third sub-pixel region CC into second color light L2 (e.g., red light) and third color light L3 (e.g., green light), respectively. The second color light L2, the third color light L3, and the first color light L1 emitted from the first sub-pixel region AA are mixed to realize full-color display of the display panel 1000.

The beneficial effects that can be achieved by the display panel 1000 provided in some embodiments of the present disclosure are the same as the beneficial effects that can be achieved by the color conversion substrate 100 provided in the above technical solutions, and details will not be repeated here.

In some embodiments, as shown in FIGS. 1 and 6, the display panel further includes a filling layer 300 located between the light-emitting substrate 200 and the color conversion substrate 100.

By providing the filling layer 300 between the light-emitting substrate 200 and the color conversion substrate 100, the cell gap between the color conversion substrate 100 and the light-emitting substrate 200 may be filled, so that the light-emitting substrate 200 and the color conversion substrate 100 may be adhered together.

For example, a material of the filling layer 300 is an acrylic polymer material or an epoxy polymer material.

For example, a thickness of the filling layer 300 may be in a range of 10 μm to 20 μm, inclusive; for example, it may be 10 μm, 12 μm, 15 μm, 18 μm or 20 μm.

In some embodiments, the light-emitting substrate 200 includes any one of an OLED light-emitting substrate 200, a light-emitting diode (LED) light-emitting substrate 200, a micro LED light-emitting substrate 200, or a mini LED light-emitting substrate 200.

Based on the above light-emitting substrates 200, the display panel 1000 may be an OLED panel, an OLED TV, a micro LED panel, a micro LED TV, a mini LED panel, a mini LED TV, a monitor, a mobile phone, a navigator, or any other product or component with a display function. The display panel 1000 may be any display panel 1000 that displays images whether in motion (e.g., a video) or stationary (e.g., static images), and whether textual or graphical. More specifically, it is expected that the display panel 1000 in the embodiments may be implemented in or associated with a plurality of electronic devices. The plurality of electronic devices may include (but are not limit to), for example, mobile phones, wireless devices, personal digital assistants (PDAs), hand-held or portable computers, GPS receivers/navigators, cameras, MP4 video players, video cameras, game consoles, watches, clocks, calculators, TV monitors, flat panel displays, computer monitors, car displays (e.g., odometer displays), navigators, cockpit controllers and/or displays, camera view displays (e.g., rear view camera displays in vehicles), electronic photos, electronic billboards or indicators, projectors, building structures, packagings and aesthetic structures (e.g., a display for an image of a piece of jewelry), etc.

In some embodiments, as shown in FIGS. 1 and 6, the light-emitting substrate 200 is an OLED light-emitting substrate 200; the OLED light-emitting substrate 200 includes a cathode 220 and an anode 210 disposed opposite to each other, and at least two light-emitting units 230 disposed between the cathode 220 and the anode 210. The light-emitting unit 230 includes a light-emitting layer 231, and the light-emitting layer 231 is configured to emit the first color light L1 to the color conversion substrate 100.

In a case where the material of the first color conversion portion 121 includes a first quantum dot material, the material of the second color conversion portion 122 includes a second quantum dot material, and the light-emitting substrate 200 is an OLED light-emitting substrate 200, the display panel 1000 is a quantum dot organic light-emitting diode (QD-OLED) display panel, and the OLED light-emitting substrate 200 that emits the first color light L1 (e.g., blue light) may be used as an excitation light source, and the first color conversion portion 121 containing the first quantum dot material (e.g., a red quantum dot material) and the second color conversion portion 122 containing the second quantum dot material (e.g., a green quantum dot material) are used as the color conversion layer (CCL) 120. In this case, the display panel 1000 may combine the advantages of high brightness, high color volume and high efficiency of quantum dots, as well as the advantages of true black state, high contrast, wide viewing angle and wide color gamut of OLED devices to achieve high-quality display effects and the advantages of wide color gamut, high color conversion efficiency (CCE) and wide viewing angle.

The OLED light-emitting substrate 200 includes the cathode 220 and the anode 210. During operation, voltages are respectively applied to the anode 210 and the cathode 220 to generate an electric field between the anode 210 and the cathode 220, so as to drive holes in the anode 210 and electrons in the cathode 220 to be recombined to emit first color light L1.

In some embodiments, a material of the light-emitting layer 231 includes a guest material, and the guest material is configured to emit the first color light L1.

For example, the guest material may be one or more of a fluorescent material, a phosphorescent material, and a thermally activated delayed fluorescent material. The fluorescent material is, for example, 4-dicyanomethylene-6-(p-dimethylaminostyryl)-2-methyl-4H-pyran (DCM), 4-(dicyanomethylene)-2-methyl-6-vinylene-4-pyran (DCJ), tris(8-hydroxyquinoline)aluminum (Alq₃) or 4,4′-bis(2,2-diphenyl-ethene-1-yl)-4,4′-dimethylphenyl (DPVPi); the phosphorescent material is, for example, Pt707, 23H-porphyrin-platinum complex (PtOEP), Bis (4,6-difluorophenylpyridinato-N,C2) picolinatoiridium (FirPic) or tris-(2-phenyl pyridine) iridium (III) (Ir(ppy)₃); the thermally activated delayed fluorescence material is, for example, DACR-DPTX, TPA-DMAC or 2,4,5,6-tetrakis (carbazol-9-yl)-1,3-dicyanobenze (4CzIPN).

For example, the wavelength of the first color light L1 emitted by the light-emitting layer 231 may be in a range of 450 nm to 470 nm, inclusive; for example, it may be 450 nm, 455 nm, 460 nm, 465 nm or 470 nm. In this case, the first color light L1 is blue light.

For example, the full width at half maxima of the emission spectrum of the first color light L1 emitted by the light-emitting layer 231 is in a range of 15 nm to 30 nm, inclusive; for example, it may be 15 nm, 20 nm, 25 nm or 30 nm. In this way, the color purity of the first color light L1 emitted by the light-emitting substrate 200 may be improved.

In some embodiments, the light-emitting unit 230 further includes: a hole transport functional layer disposed between the light-emitting layer 231 and the anode 210, and/or an electron transport functional layer disposed between the light-emitting layer 231 and the cathode 220. The hole transport functional layer includes, for example, at least one of a hole injection layer, a hole transport layer and an electron blocking layer, so that the hole transport performance may be improved. The electron transport functional layer includes, for example, at least one of an electron injection layer, an electron transport layer and a hole blocking layer, so that the electron transport performance may be improved.

In some examples, as shown in FIGS. 1 and 6, the anode 210 may be located on a side of the light-emitting unit 230 away from the color conversion substrate 100, and the cathode 220 may be located on a side of the light-emitting unit 230 proximate to the color conversion substrate 100. In this case, the anode 210, the at least two light-emitting units 230, and the cathode 220 are arranged in sequence in the second direction Y, and the anode 210, the at least two light-emitting units 230, and the cathode 220 are arranged in sequence in a direction toward the color conversion substrate 100. In some other examples, the cathode 220 may be located on a side of the light-emitting unit 230 away from the color conversion substrate 100, and the anode 210 may be located on a side of the light-emitting unit 230 proximate to the color conversion substrate 100.

The light-emitting substrate 200 includes at least two light-emitting units 230 (e.g., including n light-emitting units 230), and is a laminated light-emitting substrate 200. With such an arrangement, firstly, since OLEDs are driven by current to emit light, under a same current density, the luminance of the laminated OLED light-emitting substrate 200 composed of n identical light-emitting units 230 is n times the luminance of the traditional OLED light-emitting substrate 200 composed of a single light-emitting unit 230. Therefore, the current efficiency of the laminated OLED light-emitting substrate 200 is n times that of the conventional OLED light-emitting substrate 200. Secondly, the OLED light-emitting substrate 200 operates at a certain luminance, and at a same luminance, the current density for driving the laminated OLED light-emitting substrate 200 is 1/n of the current density for driving the conventional OLED light-emitting substrate 200. The greater the current density for driving the OLED light-emitting substrate 200 is, the faster the OLED light-emitting substrate 200 ages and the shorter the service life is. Therefore, the service life of the laminated OLED light-emitting substrate 200 is extended.

In some embodiments, as shown in FIGS. 1 and 6, the light-emitting substrate 200 further includes a charge generating layer 240, and the charge generating layer 240 is located between two adjacent light-emitting units 230 among a plurality of light-emitting units 230.

Through the charge generating layer 240, the plurality of light-emitting units 230 may be sequentially connected in a direction (e.g., the second direction Y) perpendicular to a light exit surface. Moreover, the charge generating layer 240 in the laminated OLED light-emitting substrate 200 not only plays a role of connecting the light-emitting units 230, but also helps to improve the generation efficiency of charges (holes or electrons), which may have a significant impact on the performance of the light-emitting substrate 200.

For example, the charge generating layer 240 may include a plurality of stacked inorganic material layers, such as lithium (Li)/calcium (Ca)/silver (Ag), lithium fluoride (LiF)/aluminum (Al)/Aurum (Au), or Al/tungsten trioxide (WO₃)/Au. Alternatively, the charge generating layer 240 may include an inorganic material layer and an organic material layer that are stacked, such as Alq₃ (4,7-Diphenyl-1,10-phenanthroline (Bphen)):Li, Alq₃ (2,9-Dimethyl-4,7-diphenyl-1,10-phenanthroline (BCP)):Li, Bphen: rubidium carbonate (Rb₂CO₃) or LiF/Zinc phthalocyanine (ZnPc):C₆₀/molybdenum oxide (MoO₃). Alternatively, the charge generating layer 240 may include a plurality of stacked organic material layers, such as Alq₃:Li/2,3,6,7,10,11-hexacyano-1,4,5,8,9 (HAT-CN), Bphen:Li/HAT-CN, copper (II) 1,2,3,4,8,9,10,11,15,16,17,18,22,23,24,25-Hexadecafluorophthalocyanine (F₁₆CuPc)/copper (II) phthalocyanine (α-form) (CuPc), or Li:Bphen/Al/2,3,5,6-Tetrafluoro-7,7,8,8-tetracyanoquinodimethane (F4-TCNQ)/HAT-CN.

For example, the charge generating layer (CGL) 240 may include an electron generating layer (n-CGL) and a hole generating layer (p-CGL) that are stacked. The electron generating layer is closer to the anode 210 than the hole generating layer.

In some embodiments, as shown in FIGS. 1 and 6, the light-emitting substrate 200 further includes a second encapsulation layer 250, and in a case where the cathode 220 is closer to the color conversion substrate 100 than the anode 210, the second encapsulation layer 250 may be located on a side of the cathode 220 away from the light-emitting units 230.

With such an arrangement, the second encapsulation layer 250 may be used to cover the light-emitting units 230 to avoid shortening the service life of the light-emitting substrate 200 caused by the damage to the material (e.g., the guest material) of the light-emitting units 230 due to a case that water moisture and oxygen in the external environment enter the light-emitting units 230.

For example, the second encapsulation layer 250 may include a plurality of stacked second encapsulation sub-layers, and a material of the second encapsulation sub-layer may be an organic material or an inorganic material. The organic material is, for example, an acrylic polymer material or an epoxy polymer material. The inorganic material is, for example, SiOx or SiNx. A thickness of the second encapsulation sub-layer containing the organic material may be in a range of 6 μm to 12 μm, inclusive; for example, it may be 6 μm, 7 μm, 9 μm, 11 μm or 12 μm. A thickness of the second encapsulation sub-layer containing the inorganic material may be in a range of 0.4 μm to 1.6 μm, inclusive; for example, it may be 0.4 μm, 0.8 μm, 1.2 μm or 1.6 μm.

In some examples, the light-emitting substrate further includes a driving circuit disposed on a side of the anode 210 away from the light-emitting units. The driving circuit may generate a driving current. The light-emitting substrate is driven by the driving current generated by the driving circuit to emit light.

In order to objectively evaluate the technical effects of the embodiments of the present disclosure, the technical solutions of the present disclosure will be exemplarily described in detail with the following embodiments and comparative example.

In the following embodiments, as shown in FIG. 6, the display panel 1000 includes a color conversion substrate 100, a light-emitting substrate 200, and a filling layer 300 disposed between the color conversion substrate 100 and the light-emitting substrate 200. The color conversion substrate 100 includes a substrate 110, a first color filter portion 1721, a second color filter portion 1722, a third color filter portion 1723, a light-absorbing pattern 171, a barrier pattern 160, an alignment layer 150, a first cholesteric liquid crystal unit 131, a second cholesteric liquid crystal unit 132, a third cholesteric liquid crystal unit 133, a first color conversion portion 121, a second color conversion portion 122, a light-transmitting portion 140, and a first encapsulation layer 180. The material of the first color conversion portion 121 is a red quantum dot material, and the material of the second color conversion portion 122 is a green quantum dot material. The light-emitting substrate 200 is a laminated light-emitting substrate 200, and the number of the light-emitting units 230 is three. The light-emitting substrate 200 includes a backplane (including an anode 210), a first light-emitting unit 230, a first charge generating layer 240, a second light-emitting unit 230, a second charge generating layer 240, a third light-emitting unit 230, a cathode 220 and a second encapsulation layer 250 that are stacked. The first color light L1 emitted by the first light-emitting unit 230, the second light-emitting unit 230, and the third light-emitting unit 230 is blue light. For the description of the positions, connections, materials and shapes of the above structures, reference may be made to the description of the above embodiments and will not be repeated here.

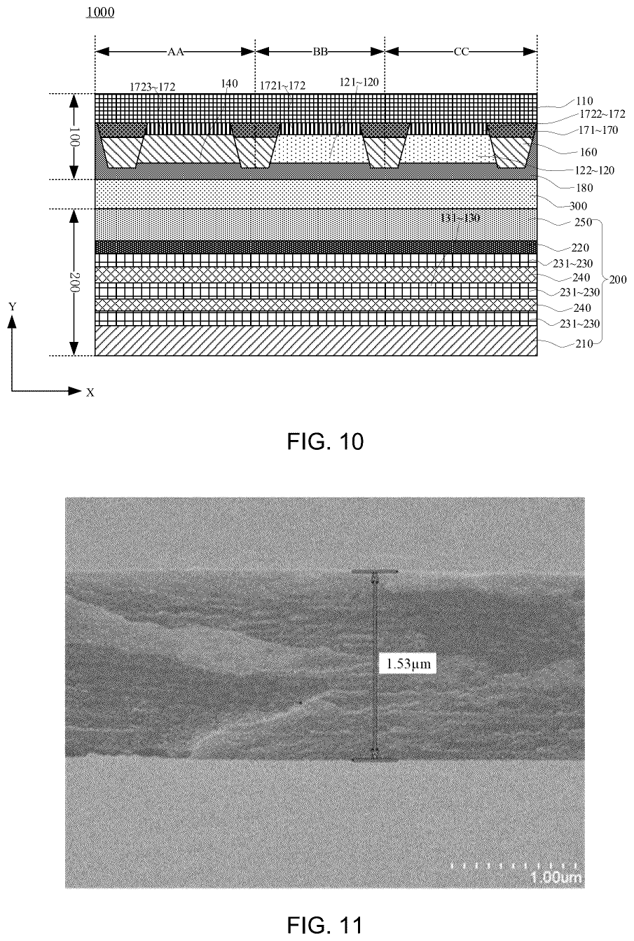

In the following comparative example, as shown in FIG. 10, in comparison with the above embodiments, the structural difference is only that there is no alignment layer 150, first cholesteric liquid crystal unit 131, second cholesteric liquid crystal unit 132, and third cholesteric liquid crystal unit 133.

In the following embodiments and comparative example, the third cholesteric liquid crystal units 133 are produced under ultraviolet light with different radiation intensities, the first cholesteric liquid crystal units 131 and the second cholesteric liquid crystal units 132 have different thicknesses and structures, and a photoelectric testing system is adopted to compare the blue light leakage rate, color conversion efficiency (CCE), color gamut, color shift, and power consumption of the display panel 1000. In the following comparative example and embodiments, the test conditions of the display panel 1000 are the same.

### Embodiment 1

Manufacturing a display panel 1000 includes P1 to P9.

In P1, a substrate 110 is provided.

In P2, a light-absorbing pattern 171 is formed on a side of the substrate 110 by coating and photolithography processes. The light-absorbing pattern 171 includes a plurality of second openings N.

In P3, a first color filter portion 1721, a second color filter portion 1722, and a third color filter portion 1723 are formed in the plurality of second openings N by coating and photolithography processes to form a light-blocking layer 170.

In P4, a barrier pattern 160 is formed on a side of the light-blocking layer 170 away from the substrate 110 by coating and photolithography processes. The barrier pattern 160 includes a plurality of first openings Q.

In P5, the barrier pattern 160 is coated, on a side away from the light-blocking layer 170, with a material of an initial alignment layer to form the initial alignment layer, and a photo-alignment process is performed on the initial alignment layer to form an alignment layer 150 located in the second openings N.

In P6, referring to the above steps R1 to R6, a cholesteric liquid crystal layer 130 is formed on a side of the alignment layer 150 away from the light-blocking layer 170.

In R1 and R4, the precursor material includes liquid crystal monomers, a chiral additive and a photoinitiator, and a mass ratio of the three is 93:3:4. The structure of the liquid crystal monomer is the structure shown in structural formula (II); the structure of the photoinitiator is the structure shown in structural formula (III). In R1, the structure of the chiral additive is the structure shown in structural formula (IV), and the thickness of the first sub-layer of the initial cholesteric liquid crystal layer 130a is 1.5 μm; in R4, the structure of the chiral additive is the structure shown in structural formula (V), and the thickness of the second sub-layer of the initial cholesteric liquid crystal layer 130a is 1.5 μm.

In R2 and R5, the irradiation intensity of ultraviolet light on the first initial cholesteric liquid crystal unit 131a and the second initial cholesteric liquid crystal unit 132a is 7 mW/cm², and the irradiation time of the ultraviolet light for the first initial cholesteric liquid crystal unit 131a and the second initial cholesteric liquid crystal unit 132a is 5 min. In R3 and R6, the heating temperature of the third initial cholesteric liquid crystal unit 133a is 140° C., the cooling rate of the third initial cholesteric liquid crystal unit 133a is 3° C./min, and the irradiation intensity of ultraviolet light on the third initial cholesteric liquid crystal unit 133a is 3.0 mW/cm².

In P7, a first color conversion portion 121 is formed on a side of the first cholesteric liquid crystal unit 131 away from the alignment layer 150 by coating and photolithography processes; a second color conversion portion 122 is formed on a side of the second cholesteric liquid crystal unit 132 away from the alignment layer 150 by coating and photolithography processes; and a light-transmitting portion 140 is formed on a side of the third cholesteric liquid crystal unit 133 away from the alignment layer 150 by coating and photolithography processes.

In P8, a first encapsulation layer 180 is formed on a side of the first color conversion portion 121, the second color conversion portion 122 and the light-transmitting portion 140 away from the cholesteric liquid crystal layer 130 by coating and photolithography processes; and a material of the first encapsulation layer 180 is an inorganic material.

In P9, a cell-assembling process is adopted to adhere the color conversion substrate 100 to the light-emitting substrate 200 together.

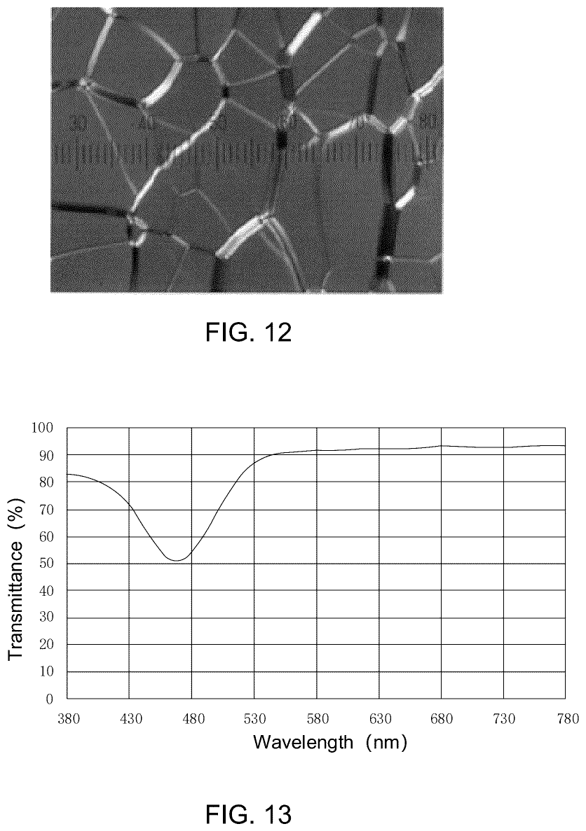

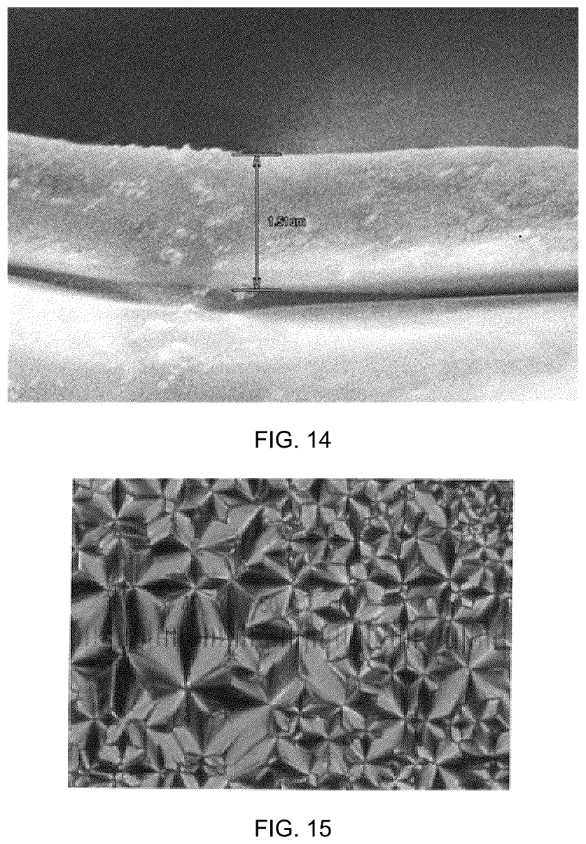

After forming the first chiral liquid crystal unit 1311, the third chiral liquid crystal unit 1321 and the first sub-unit of the third cholesteric liquid crystal unit 133 in P6, the microscopic morphology of the first cholesteric liquid crystal unit 131 is measured, and the result is shown in FIG. 11; the polarizing microscope texture of the first cholesteric liquid crystal unit 131 is measured, and the result is shown in FIG. 12; the transmission spectrum of the first cholesteric liquid crystal unit 131 is measured, and the result is shown in FIG. 13; the microscopic morphology of the third cholesteric liquid crystal unit 133 is measured, and the result is shown in FIG. 14; the polarizing microscope texture of the third cholesteric liquid crystal unit 133 is measured, and the result is shown in FIG. 15. FIGS. 11 and 14 shows results measured using a scanning electron microscope, model S-4800, with a test voltage of 5 kV.

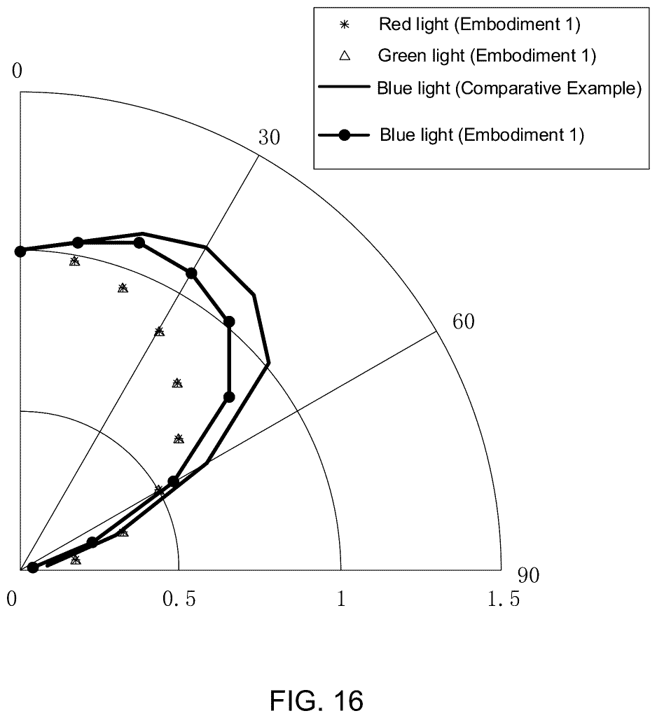

After P9, the angular distribution of light intensity of the first sub-pixel region AA, the second sub-pixel region BB, and the third sub-pixel region CC in the display panel 1000 are measured, and the results are shown in FIG. 16.

### Embodiment 2

Referring to the above method in P1 to P9, a display panel 1000 is manufactured. The manufacturing conditions are the same as those in Embodiment 1 except for the thickness of the first sub-layer of the initial cholesteric liquid crystal layer 130a, the thickness of the second sub-layer of the initial cholesteric liquid crystal layer 130a, and the irradiation intensity of ultraviolet light on the third initial cholesteric liquid crystal unit 133a.

In this embodiment, the thickness of the first sub-layer of the initial cholesteric liquid crystal layer 130a is 1.0 μm; the thickness of the second sub-layer of the initial cholesteric liquid crystal layer 130a is 1.0 μm. The irradiation intensity of ultraviolet light on the third initial cholesteric liquid crystal unit 133a is 3.0 mW/cm².

### Embodiment 3

Referring to the above method in P1 to P9, a display panel 1000 is manufactured. The manufacturing conditions are the same as those in Embodiment 1 except for the thickness of the first sub-layer of the initial cholesteric liquid crystal layer 130a, the thickness of the second sub-layer of the initial cholesteric liquid crystal layer 130a, and the irradiation intensity of ultraviolet light on the third initial cholesteric liquid crystal unit 133a.

In this embodiment, the thickness of the first sub-layer of the initial cholesteric liquid crystal layer 130a is 2.0 μm; the thickness of the second sub-layer of the initial cholesteric liquid crystal layer 130a is 2.0 μm. The irradiation intensity of ultraviolet light on the third initial cholesteric liquid crystal unit 133a is 3.0 mW/cm².

### Embodiment 4

Referring to the above method in P1 to P9, a display panel 1000 is manufactured. The manufacturing conditions are the same as those in Embodiment 1 except for the thickness of the first sub-layer of the initial cholesteric liquid crystal layer 130a, the thickness of the second sub-layer of the initial cholesteric liquid crystal layer 130a, and the irradiation intensity of ultraviolet light on the third initial cholesteric liquid crystal unit 133a.

In this embodiment, the thickness of the first sub-layer of the initial cholesteric liquid crystal layer 130a is 1.5 μm; the thickness of the second sub-layer of the initial cholesteric liquid crystal layer 130a is 1.5 μm. The irradiation intensity of ultraviolet light on the third initial cholesteric liquid crystal unit 133a is 1.0 mW/cm².

### Embodiment 5

Referring to the above method in P1 to P9, a display panel 1000 is manufactured. The manufacturing conditions are the same as those in Embodiment 1 except for the thickness of the first sub-layer of the initial cholesteric liquid crystal layer 130a, the thickness of the second sub-layer of the initial cholesteric liquid crystal layer 130a, and the irradiation intensity of ultraviolet light on the third initial cholesteric liquid crystal unit 133a.

In this embodiment, the thickness of the first sub-layer of the initial cholesteric liquid crystal layer 130a is 1.5 μm; the thickness of the second sub-layer of the initial cholesteric liquid crystal layer 130a is 1.5 μm. The irradiation intensity of ultraviolet light on the third initial cholesteric liquid crystal unit 133a is 5.0 mW/cm².

### Embodiment 6

Referring to the method in P1 to P9, a display panel 1000 is manufactured. The manufacturing conditions are the same as those in Embodiment 1 except for P6.

In this embodiment, in P6, referring to the above method in R1 to R3, a cholesteric liquid crystal layer 130 is formed on a side of the alignment layer 150 away from the light-blocking layer 170. That is, in this embodiment, in the cholesteric liquid crystal layer 130 formed in P6, the first cholesteric liquid crystal unit 131 only includes the first chiral liquid crystal layer, the second cholesteric liquid crystal unit 132 only includes the third chiral liquid crystal layer, and the third cholesteric liquid crystal unit 133 only includes the first sub-unit of the third cholesteric liquid crystal unit 133.

In R1, the precursor includes liquid crystal monomers, a chiral additive and a photoinitiator, and a mass ratio of the three is 93:3:4. The structure of the liquid crystal monomer is the structure shown in structural formula (II); the structure of the photoinitiator is the structure shown in structural formula (III), and the structure of the chiral additive is the structure shown in structural formula (IV). The thickness of the first sub-layer of the initial cholesteric liquid crystal layer 130a is 3.0 μm.

In R2, the irradiation intensity of ultraviolet light on the first initial cholesteric liquid crystal unit 131a and the second initial cholesteric liquid crystal unit 132a is 7 mW/cm², and the irradiation time of ultraviolet light for the first initial cholesteric liquid crystal unit 131a and the second initial cholesteric liquid crystal unit 132a is 5 min. In R3, the heating temperature of the third initial cholesteric liquid crystal unit 133a is 140° C., the cooling rate of the third initial cholesteric liquid crystal unit 133a is 3° C./min, and the irradiation intensity of ultraviolet light on the third initial cholesteric liquid crystal unit 133a is 3.0 mW/cm².

### Embodiment 7

Referring to the above method in P1 to P9, a display panel 1000 is manufactured. The manufacturing conditions are the same as those in Embodiment 1 except for P6.

In this embodiment, in P6, referring to the above method in R4 to R6, a cholesteric liquid crystal layer 130 is formed on a side of the alignment layer 150 away from the light-blocking layer 170. That is, in this embodiment, in the cholesteric liquid crystal layer 130 formed in P6, the first cholesteric liquid crystal unit 131 only includes the second chiral liquid crystal layer, the second cholesteric liquid crystal unit 132 only includes the fourth chiral liquid crystal layer, and the third cholesteric liquid crystal unit 133 only includes the second sub-unit of the third cholesteric liquid crystal unit 133.

In R4, the precursor includes liquid crystal monomers, a chiral additive and a photoinitiator, and a mass ratio of the three is 93:3:4. The structure of the liquid crystal monomer is the structure shown in structural formula (II); the structure of the photoinitiator is the structure shown in structural formula (III), and the structure of the chiral additive is the structure shown in structural formula (V). The thickness of the second sub-layer of the initial cholesteric liquid crystal layer 130a is 3.0 μm.

In R5, the irradiation intensity of ultraviolet light on the first initial cholesteric liquid crystal unit 131a and the second initial cholesteric liquid crystal unit 132a is 7 mW/cm², and the irradiation time of ultraviolet light for the first initial cholesteric liquid crystal unit 131a and the second initial cholesteric liquid crystal unit 132a is 5 min. In R6, the heating temperature of the third initial cholesteric liquid crystal unit 133a is 140° C., the cooling rate of the third initial cholesteric liquid crystal unit 133a is 3° C./min, and the irradiation intensity of ultraviolet light on the third initial cholesteric liquid crystal unit 133a is 3.0 mW/cm².

### Comparative Example

Referring to the above method in P1 to P4 and P7 to P9, a display panel 1000 is manufactured. However, in P7, the first color conversion portion 121, the second color conversion portion 122 and the light-transmitting portion 140 are formed in the plurality of second openings N by coating and photolithography processes. That is, in the comparative example, there is no cholesteric liquid crystal layer 130 in the color conversion substrate 100.

In this comparative example, after P9, the angular distribution of light intensity of the first sub-pixel region AA of the display panel 1000 is measured, and the result is shown in FIG. 16 and is compared with the angular distribution of light intensity measured in Embodiment 1.

By comparing Comparative Example and Embodiment 1, as can be known from FIG. 16 that, in comparison with the angular distribution of light intensity of the blue light emitted from the first sub-pixel region AA in the comparative example, the angular distribution of light intensity of the blue light emitted from the first sub-pixel region AA in Embodiment 1 is closer to the angular distribution of light intensity of the red light emitted from the second sub-pixel region BB and the angular distribution of light intensity of the green light emitted from the third sub-pixel region CC. This is because in Embodiment 1, a third cholesteric liquid crystal unit 133 is provided between the substrate 110 and the light-transmitting portion 140, and the cholesteric liquid crystal in the third cholesteric liquid crystal unit 133 is in a focal conic state, which may scatter a part of the first color light L1 that near the front viewing angle toward a wide viewing angle direction. In comparison with the comparative example, the angular distribution of the first color light L1 emitted from the first sub-pixel region AA is wider, which may improve the matching of the angular distributions of the light emitted from the first sub-pixel region AA, the second sub-pixel region BB and the third sub-pixel region CC, and may alleviate the problem of angular color shift.

Based on the above Embodiments 1 to 7 and the comparative example, the blue light leakage rate, color conversion efficiency (CCE), color gamut, color shift, and power consumption of the display panel 1000 in Embodiments 1 to 7 and the comparative example are measured by using a photoelectric testing system. The data results of blue light leakage rate, color conversion efficiency (CCE), color gamut, color shift, and power consumption are based on the comparative example, and the test results are shown in the following Table 1.

TABLE 1

| | Blue light | Color | | | |
|---|---|---|---|---|---|
| | leakage | conversion | Color | Color | Power |
| | rate | efficiency | gamut | shift | consumption |
| | (%) | (%) | (%) | (%) | (%) |
| Comparative | 100 | 100 | 100 | 100 | 100 |
| Example | | | | | |
| Embodiment 1 | 25 | 130 | 120 | 50 | 80 |
| Embodiment 2 | 28 | 125 | 115 | 60 | 85 |
| Embodiment 3 | 24 | 129 | 119 | 49 | 81 |
| Embodiment 4 | 23 | 129 | 119 | 55 | 82 |
| Embodiment 5 | 24 | 129 | 118 | 52 | 81 |
| Embodiment 6 | 50 | 113 | 108 | 49 | 92 |
| Embodiment 7 | 51 | 114 | 109 | 50 | 93 |

It will be noted that, the blue light leakage rate in Table 1 is an average value of the blue light leakage rates of the light emitted from the second sub-pixel region BB and the third sub-pixel region CC. The color conversion efficiency in Table 1 is an average value of the color conversion efficiencies of the first color conversion portion 121 and the second color conversion portion 122. The color gamut in Table 1 is determined based on the CIE 1931 chromaticity diagram. The color shift in Table 1 is the result of measurement at a viewing angle of 45°.

Referring to Table 1, in comparison with the comparative example, in Embodiments 1 to 7, the blue light leakage rate is lower, the color conversion efficiency is higher, the color gamut is wider, and the power consumption is lower. This is because in the color conversion substrate 100 in Embodiments 1 to 7, a first cholesteric liquid crystal unit 131 is provided between the substrate 110 and the first color conversion portion 121, a second cholesteric liquid crystal unit 132 is provided between the substrate 110 and the second color conversion portion 122, and the cholesteric liquid crystals in the first cholesteric liquid crystal unit 131 and the second cholesteric liquid crystal unit 132 are in a planar state, so that the first color light L1 that passes through the first color conversion portion 121 and the second color conversion portion 122 but is not converted may be reflected by the first cholesteric liquid crystal unit 131 and the second cholesteric liquid crystal unit 132 back to the first color conversion portion 121 and the second color conversion portion 122, excite the color conversion materials in the first color conversion portion 121 and the second color conversion portion 122 and be converted into the second color light L2 and the third color light L3. In this way, firstly, the first color light L1 leaking from the second sub-pixel region BB and the third sub-pixel region CC may be reduced, so that the blue light leakage rate is lower. Secondly, the reflected first color light L1 may reenter the first color conversion portion 121 and the second color conversion portion 122 to excite the color conversion materials in the first color conversion portion 121 and the second color conversion portion 122 and be converted into the second color light L2 and the third color light L3, so that the color conversion efficiency is increased and the power consumption of the display panel 1000 is reduced. Thirdly, the color purity of the display panel 1000 may be improved, and it is possible to avoid the interference caused by a case that the leaked first color light L1 enters adjacent sub-pixel regions, so that the color gamut of the display panel 1000 may be widened.

Referring to Table 1, in comparison with Embodiments 6 and 7, in Embodiments 1 to 5, the blue light leakage rate is lower, the color conversion efficiency is higher, the color gamut is wider, and the power consumption is lower. This is because in the color conversion substrate 100 in Embodiments 1 to 5, the first cholesteric liquid crystal unit 131 includes a first chiral liquid crystal unit 1311 and a second chiral liquid crystal unit 1312 having opposite helical directions, and the second cholesteric liquid crystal unit 132 includes a third chiral liquid crystal unit 1321 and a fourth chiral liquid crystal unit 1322 having opposite helical directions. In this way, a part of the first color light L1 having the same helical direction as the liquid crystal molecules in the first chiral liquid crystal unit 1311 and the third chiral liquid crystal unit 1321 may be reflected by the first chiral liquid crystal unit 1311 and the third chiral liquid crystal unit 1321 back to the first color conversion portion 121 and the second color conversion portion 122 to be converted into the second color light L2 and the third color light L3; meanwhile, a part of the first color light L1 having a helical direction opposite to that of the liquid crystal molecules in the first chiral liquid crystal unit 1311 and the third chiral liquid crystal unit 1321 may be reflected by the second chiral liquid crystal unit 1312 and the fourth chiral liquid crystal unit 1322 back to the first color conversion portion 121 and the second color conversion portion 122 to be converted into the second color light L2 and the third color light L3. In this way, the reflectivity of the first cholesteric liquid crystal unit 131 and the second cholesteric liquid crystal unit 132 to the first color light L1 may be improved. Therefore, firstly, the first color light L1 leaking from the second sub-pixel region BB and the third sub-pixel region CC may be reduced, so that the blue light leakage rate is lower. Secondly, the reflected first color light L1 may reenter the first color conversion portion 121 and the second color conversion portion 122 to excite the color conversion materials in the first color conversion portion 121 and the second color conversion portion 122 and be converted into the second color light L2 and the third color light L3, so that the color conversion efficiency is increased and the power consumption of the display panel 1000 is reduced. Thirdly, the color purity of the display panel 1000 may be improved, and it is possible to avoid the interference caused by a case that the leaked first color light L1 enters adjacent sub-pixel regions, so that the color gamut of the display panel 1000 may be widened.

Referring to Table 1, in comparison with the comparative example, in Embodiments 1 to 7, the color shift is lower. This is because in Embodiments 1 to 7, a third cholesteric liquid crystal unit 133 is provided between the substrate 110 and the light-transmitting portion 140, and the cholesteric liquid crystals in the third cholesteric liquid crystal unit 133 is in a focal conic state, which may scatter a part of the first color light L1 that near the front viewing angle toward a wide viewing angle direction. In comparison with the comparative example, in Embodiments 1 to 7, the angular distribution of the first color light L1 emitted from the first sub-pixel region AA is wider, which may improve the matching of the angular distributions of the light emitted from the first sub-pixel region AA, the second sub-pixel region BB and the third sub-pixel region CC, and may alleviate the problem of angular color shift.

The above are only specific embodiments of the present disclosure, but the protection scope of the present disclosure is not limited thereto, and variations or substitutions that any person skilled in the art may conceive of within the technical scope of the present disclosure, should fall within the protection scope of the present disclosure. Therefore, the protection scope of the present disclosure should be subjected to the protection scope of the claims.

1. A color conversion substrate, comprising:
a substrate;
a color conversion layer located on a side of the substrate, wherein the color conversion layer includes a first color conversion portion, and the first color conversion portion is configured to convert first color light incident on the first color conversion portion into second color light; and
a cholesteric liquid crystal layer, wherein the cholesteric liquid crystal layer includes a first cholesteric liquid crystal unit located between the substrate and the first color conversion portion, and the first cholesteric liquid crystal unit is configured to reflect unconverted light in the first color light back to the first color conversion portion.

2. The color conversion substrate according to claim 1, wherein the color conversion layer further includes a second color conversion portion arranged in a first direction with the first color conversion portion, the first direction intersects with a thickness direction of the substrate, and the second color conversion portion is configured to convert first color light incident on the second color conversion portion into third color light; and
the cholesteric liquid crystal layer further includes a second cholesteric liquid crystal unit located between the substrate and the second color conversion portion, and the second cholesteric liquid crystal unit is configured to reflect unconverted light in the first color light back to the second color conversion portion.

3. The color conversion substrate according to claim 2, wherein cholesteric liquid crystals in the first cholesteric liquid crystal unit and the second cholesteric liquid crystal unit are in a planar state.

4. The color conversion substrate according to claim 1, further comprising a light-transmitting portion arranged in a first direction with the color conversion layer, wherein the first direction intersects with a thickness direction of the substrate, and the first color light passes through the light-transmitting portion; and
the cholesteric liquid crystal layer further includes a third cholesteric liquid crystal unit located between the substrate and the light-transmitting portion, and the third cholesteric liquid crystal unit is configured to scatter a part of the first color light passing through the light-transmitting portion that near a front viewing angle toward a large viewing angle direction.

5. The color conversion substrate according to claim 4, wherein cholesteric liquid crystals in the third cholesteric liquid crystal unit are in a focal conic state.

6. The color conversion substrate according to claim 1, wherein the first cholesteric liquid crystal unit includes a first chiral liquid crystal unit and a second chiral liquid crystal unit that are stacked; a helical direction of liquid crystal molecules in the first chiral liquid crystal unit is opposite to a helical direction of liquid crystal molecules in the second chiral liquid crystal unit; and/or
the cholesteric liquid crystal layer further includes a second cholesteric liquid crystal unit, the second cholesteric liquid crystal unit includes a third chiral liquid crystal unit and a fourth chiral liquid crystal unit that are stacked; a helical direction of liquid crystal molecules in the third chiral liquid crystal unit is opposite to a helical direction of liquid crystal molecules in the fourth chiral liquid crystal unit.

7. The color conversion substrate according to claim 2, wherein a pitch of liquid crystal molecules in the first cholesteric liquid crystal unit is greater than or equal to 270 nm and less than or equal to 310 nm; a pitch of liquid crystal molecules in the second cholesteric liquid crystal unit is greater than or equal to 270 nm and less than or equal to 310 nm.

8. The color conversion substrate according to claim 2, wherein the first color light is blue light; a central reflection wavelength of the first cholesteric liquid crystal unit is greater than or equal to 450 nm and less than or equal to 470 nm; a central reflection wavelength of the second cholesteric liquid crystal unit is greater than or equal to 450 nm and less than or equal to 470 nm.

9. The color conversion substrate according to claim 2, wherein a full width at half maxima of a transmission spectrum of the first cholesteric liquid crystal unit is greater than or equal to 70 nm and less than or equal to 100 nm; a full width at half maxima of a transmission spectrum of the second cholesteric liquid crystal unit is greater than or equal to 70 nm and less than or equal to 100 nm.

10. The color conversion substrate according to claim 2, further comprising an alignment layer located between the cholesteric liquid crystal layer and the substrate, wherein the alignment layer includes a first alignment portion, a second alignment portion and a third alignment portion that are arranged in the first direction; the first alignment portion is configured to align liquid crystal molecules in the first cholesteric liquid crystal unit; the second alignment portion is configured to align liquid crystal molecules in the second cholesteric liquid crystal unit; and the third alignment portion is configured to align liquid crystal molecules in the third cholesteric liquid crystal unit.

11. The color conversion substrate according to claim 4, wherein haze of the third cholesteric liquid crystal unit is greater than or equal to 3% and less than or equal to 8% and/or a transmittance of the third cholesteric liquid crystal unit to light in a first wavelength band is greater than or equal to 90%; minimum wavelength of the first wavelength band is 450 nm, and maximum wavelength of the first wavelength band is 470 nm.

12. (canceled)

13. The color conversion substrate according to claim 1, wherein a thickness of the cholesteric liquid crystal layer is greater than or equal to 2 μm and less than or equal to 6 μm.

14. The color conversion substrate according to claim 2, wherein a material of the first color conversion portion includes a first quantum dot material; a material of the second color conversion portion includes a second quantum dot material.

15. The color conversion substrate according to claim 4, further comprising a barrier pattern, wherein the barrier pattern includes a plurality of first openings; the first color conversion portion and the first cholesteric liquid crystal unit are located in a first opening; the second color conversion portion and the second cholesteric liquid crystal unit are located in another first opening; the light-transmitting portion and the third cholesteric liquid crystal unit are located in yet another first opening.

16. The color conversion substrate according to claim 15, further comprising a light-blocking layer located between the cholesteric liquid crystal layer and the substrate, wherein the light-blocking layer includes:
a light-absorbing pattern including a plurality of second openings, the plurality of second openings being directly opposite to the plurality of first openings; and
a plurality of color filter portions located on a side of the substrate proximate to the cholesteric liquid crystal layer; a color filter portion of the plurality of color filter portions is disposed in a second opening of the plurality of second openings; the plurality of color filter portions include a first color filter portion directly opposite to the first color conversion portion, a second color filter portion directly opposite to the second color conversion portion, and a third color filter portion directly opposite to the light-transmitting portion.

17. A manufacturing method of a color conversion substrate, comprising:
providing a substrate;
forming a cholesteric liquid crystal layer on a side of the substrate; the cholesteric liquid crystal layer including a first cholesteric liquid crystal unit;
forming a color conversion layer on a side of the cholesteric liquid crystal layer away from the substrate; the color conversion layer including a first color conversion portion located on a side of the first cholesteric liquid crystal unit away from the substrate;
wherein the first color conversion portion is configured to convert first color light incident on the first color conversion portion into second color light; the first cholesteric liquid crystal unit is configured to reflect unconverted light in the first color light back to the first color conversion portion.

18. The manufacturing method of the color conversion substrate according to claim 17, wherein the color conversion substrate further includes a light-transmitting portion arranged in a first direction with the color conversion layer, the first direction intersects with a thickness direction of the substrate, and the first color light is able to pass through the light-transmitting portion;
the color conversion layer further includes a second color conversion portion arranged in the first direction with the first color conversion portion, and the second color conversion portion is configured to convert first color light incident on the second color conversion portion into third color light; and
forming the cholesteric liquid crystal layer on the side of the substrate includes:
forming an initial cholesteric liquid crystal layer on the side of the substrate, the initial cholesteric liquid crystal layer including a first initial cholesteric liquid crystal unit, a second initial cholesteric liquid crystal unit and a third initial cholesteric liquid crystal unit;
forming the first initial cholesteric liquid crystal unit into a first cholesteric liquid crystal unit, and forming the second initial cholesteric liquid crystal unit into a second cholesteric liquid crystal unit; the second cholesteric liquid crystal unit being located between the substrate and the second color conversion portion; and the second cholesteric liquid crystal unit being configured to reflect unconverted light in the first color light back to the second color conversion portion; and
forming the third initial cholesteric liquid crystal unit into a third cholesteric liquid crystal unit; the third cholesteric liquid crystal unit being located between the substrate and the light-transmitting portion, and the third cholesteric liquid crystal unit being configured to scatter a part of the first color light passing through the light-transmitting portion that near a front viewing angle toward a large viewing angle direction.

19. A display panel, comprising: the color conversion substrate according to claim 1, and
a light-emitting substrate, wherein the light-emitting substrate is opposite to the color conversion substrate, and the light-emitting substrate is configured to emit the first color light.

20. The display panel according to claim 19, wherein the light-emitting substrate includes any one of an organic light-emitting diode (OLED) light-emitting substrate, a light-emitting diode (LED) light-emitting substrate, a micro LED light-emitting substrate or a mini LED light-emitting substrate.

21. The display panel according to claim 19, wherein the light-emitting substrate is an OLED light-emitting substrate, and the OLED light-emitting substrate includes a cathode and an anode disposed opposite to each other, and at least two light-emitting units disposed between the cathode and the anode; and
a light-emitting unit of the at least two light-emitting units includes a light-emitting layer, and the light-emitting layer is configured to emit the first color light to the color conversion substrate.
